(19) United States
(12) Patent Application Publication
(10) Pub. No.: US 2026/0253624 A1
(43) Pub. Date: Aug. 27, 2026

(54) THREE-DIMENSIONAL MEMORY DEVICE INCLUDING CAPACITORS LOCATED IN DUMMY MEMORY BLOCK AND METHODS FOR FORMING THE SAME

(71) Applicant: Sandisk Technologies, Inc., Milpitas, CA (US)

(72) Inventor: Takumi MORIYAMA, Yokkaichi (JP)

(21) Appl. No.: 19/061,462

(22) Filed: Feb. 24, 2025

(51) Int. Cl. G11C 5/10; G11C 5/06; G11C 16/04; H10B 43/10; H10B 43/27; H10B 43/35

(52) U.S. Cl. CPC G11C 5/10; G11C 5/063; G11C 16/0483; H10B 43/10; H10B 43/27; H10B 43/35

(57) ABSTRACT

A semiconductor structure includes a memory block including a first alternating stack of word lines and insulating layers and vertical NAND strings vertically extending through the first alternating stack. The semiconductor structure also includes a capacitor block that is laterally separated from the memory block. The capacitor block includes a second alternating stack of dummy word lines and insulating layers, and dummy structures vertically extending through the second alternating stack. The dummy word lines function as capacitor electrodes and the insulating layers function as capacitor dielectrics of capacitor structures.

### FIELD

The present disclosure relates generally to the field of semiconductor devices, and particularly to a three-dimensional memory device containing capacitors located in a dummy memory block and methods for forming the same.

### SUMMARY

According to an aspect of the present disclosure, a semiconductor structure is provided, which comprises: a first alternating stack of first insulating layers and first electrically conductive layers that alternate along a vertical direction, wherein the first alternating stack comprises a first staircase region including first stepped surfaces and further comprises a first full-stack region in which each layer within the first alternating stack is present; first openings that vertically extends through each of the first insulating layers and each of the first electrically conductive layers in the first full-stack region; first opening fill structures that fill the first openings; electrode contact via structures contacting a respective one of the first electrically conductive layers, wherein a first layer contact via structure among the electrode contact via structures and a second electrode contact via structure among the electrode contact via structures contact a vertically neighboring pair of first electrically conductive layers within the first alternating stack to provide a capacitor structure in which an intervening first insulating layer among the first insulating layers is a capacitor dielectric; and a semiconductor circuit electrically connected to the capacitor structure and configured to operate in a circuit operational mode in which the capacitor structure functions as a capacitor component of the semiconductor circuit.

According to another aspect of the present disclosure, a method of forming a semiconductor structure is provided, which comprises: forming a vertically alternating sequence of continuous insulating layers and continuous sacrificial material layers over a substrate, the vertically alternating sequence comprising a first full-stack region and a second full-stack region; forming first openings in the first full-stack region and forming second openings in the second full-stack region; forming first opening fill structures that fill the first openings and forming memory opening fill structures in the second openings, wherein each of the memory opening fill structures comprises a respective vertical semiconductor channel and a respective vertical stack of memory elements; dividing the vertically alternating sequence and replacing remaining portions of continuous sacrificial material layers with at least one electrically conductive material, whereby a first alternating stack of first insulating layers and first electrically conductive layers is formed in an area of the first full-stack region and a second alternating stack of second insulating layers and second electrically conductive layers is formed in an area of the second full-stack region; forming electrode contact via structures on a respective one of the first electrically conductive layers, wherein a first electrode contact via structure among the electrode contact via structures and a second electrode contact via structure among the electrode contact via structures contact a vertically neighboring pair of first electrically conductive layers within the first alternating stack to provide a capacitor structure in which an intervening first insulating layer among the first insulating layers is a capacitor dielectric; and electrically connecting a semiconductor circuit to the capacitor structure, wherein the semiconductor circuit is configured to operate in a circuit operational mode in which the capacitor structure functions as a capacitor component of the semiconductor circuit.

### BRIEF DESCRIPTION OF DRAWINGS

FIG. 1 is a vertical cross-sectional view of a first exemplary structure after formation of a vertically alternating sequence of continuous insulating layers and continuous sacrificial material layers according to an embodiment of the present disclosure.

FIG. 2 is a vertical cross-sectional view of the first exemplary structure after formation of a retro-stepped dielectric material portion according to an embodiment of the present disclosure.

FIG. 3A is a vertical cross-sectional view of the first exemplary structure after formation of memory openings and support openings according to an embodiment of the present disclosure. FIG. 3B is a top-down view of the first exemplary structure of FIG. 3A. The vertical plane A-A′ is the cut plane of the vertical cross-sectional view of FIG. 3A.

FIG. 4 is a vertical cross-sectional view of the first exemplary structure after formation of sacrificial opening fill structures according to an embodiment of the present disclosure.

FIG. 5 is a vertical cross-sectional view of the first exemplary structure after formation of a support pillar structure according to an embodiment of the present disclosure.

FIG. 6A is a vertical cross-sectional view of the first exemplary structure after removal of sacrificial memory opening fill structures from the memory openings according to an embodiment of the present disclosure. FIG. 6B is a top-down view of the first exemplary structure of FIG. 6A. The vertical plane A-A′ is the cut plane of the vertical cross-sectional view of FIG. 6A.

FIGS. 7A-7F are sequential vertical cross-sectional views of a memory opening during formation of a memory opening fill structure or a dummy memory opening fill structure according to an embodiment of the present disclosure.

FIG. 8A is a vertical cross-sectional view of the first exemplary structure after formation of memory opening fill structures and dummy memory opening fill structures according to an embodiment of the present disclosure. FIG. 8B is a top-down view of the first exemplary structure of FIG. 8A. The vertical plane A-A′ is the cut plane of the vertical cross-sectional view of FIG. 8A. FIG. 8C is a vertical cross-sectional view along the vertical plane C-C′ of the first exemplary structure of FIG. 8B.

FIG. 9A is a vertical cross-sectional view of the first exemplary structure after formation of a contact-level dielectric layer and lateral isolation trenches according to an embodiment of the present disclosure. FIG. 9B is a top-down view of the first exemplary structure of FIG. 9A. The vertical plane A-A′ is the cut plane of the vertical cross-sectional view of FIG. 9A.

FIG. 10 is a vertical cross-sectional view of the first exemplary structure after formation of lateral recesses according to an embodiment of the present disclosure.

FIG. 11 is a vertical cross-sectional view of the first exemplary structure after formation of electrically conductive layers according to an embodiment of the present disclosure.

FIG. 12A is a vertical cross-sectional view of the first exemplary structure after formation of lateral isolation trench fill structures according to an embodiment of the present disclosure. FIG. 12B is a top-down view of the first exemplary structure of FIG. 12A. The vertical plane A-A′ is the cut plane of the vertical cross-sectional view of FIG. 12A. FIG. 12C is a vertical cross-sectional view along the vertical plane C-C′ of the first exemplary structure of FIG. 12B.

FIG. 13A is a vertical cross-sectional view of the first exemplary structure after formation of electrode contact via structures and layer contact via structures according to an embodiment of the present disclosure. FIG. 13B is a top-down view of the first exemplary structure of FIG. 13A. The vertical plane A-A′ is the cut plane of the vertical cross-sectional view of FIG. 13A. FIG. 13C is a vertical cross-sectional view along the vertical plane C-C′ of the first exemplary structure of FIG. 13B.

FIG. 14A is a first vertical cross-sectional view of the first exemplary structure after formation of a memory die along a cut plane that corresponds to the vertical plane A-A′ in FIG. 13B according to an embodiment of the present disclosure. FIG. 14B is a second vertical cross-sectional view of the first exemplary structure at the processing step of FIG. 14A along a cut plane that corresponds to the vertical plane C-C′ in FIG. 13B according to an embodiment of the present disclosure.

FIG. 15 is a vertical cross-sectional view of a logic die according to an embodiment of the present disclosure.

FIG. 16A is a vertical cross-sectional view of the first exemplary structure after bonding the logic die to the memory die along a cut plane that corresponds to the vertical plane A-A′ in FIG. 13B according to an embodiment of the present disclosure. FIG. 16B is a vertical cross-sectional view of the first exemplary structure after bonding to a logic die along a cut plane that corresponds to the vertical plane C-C′ in FIG. 13B according to an embodiment of the present disclosure.

FIG. 17A is a vertical cross-sectional view of the first exemplary structure after removal of the carrier substrate along a cut plane that corresponds to the vertical plane A-A′ in FIG. 13B according to an embodiment of the present disclosure. FIG. 17B is a vertical cross-sectional view of the first exemplary structure after bonding to a logic die along a cut plane that corresponds to the vertical plane C-C′ in FIG. 13B according to an embodiment of the present disclosure.

FIG. 18A is a vertical cross-sectional view of the first exemplary structure after formation of a source layer, a backside insulating layer, and source contact structures along a cut plane that corresponds to the vertical plane A-A′ in FIG. 13B according to an embodiment of the present disclosure. FIG. 18B is a vertical cross-sectional view of the first exemplary structure after bonding to a logic die along a cut plane that corresponds to the vertical plane C-C′ in FIG. 13B according to an embodiment of the present disclosure.

FIG. 19A is a vertical cross-sectional view of a second exemplary structure after formation of memory openings, support openings, and pillar openings according to an embodiment of the present disclosure. FIG. 19B is a top-down view of the second exemplary structure of FIG. 19A. The vertical plane A-A′ is the cut plane of the vertical cross-sectional view of FIG. 19A.

FIG. 20A is a vertical cross-sectional view of the second exemplary structure after formation of support pillar structures, dielectric pillar structures, and memory opening fill structures according to an embodiment of the present disclosure. FIG. 20B is a top-down view of the second exemplary structure of FIG. 20A. The vertical plane A-A′ is the cut plane of the vertical cross-sectional view of FIG. 20A. FIG. 20C is a vertical cross-sectional view along the vertical plane C-C′ of the first exemplary structure of FIG. 20B.

FIG. 21A is a vertical cross-sectional view of the second exemplary structure after formation of electrode contact via structures and layer contact via structures according to an embodiment of the present disclosure. FIG. 21B is a top-down view of the second exemplary structure of FIG. 21A. The vertical plane A-A′ is the cut plane of the vertical cross-sectional view of FIG. 21A. FIG. 21C is a vertical cross-sectional view along the vertical plane C-C′ of the second exemplary structure of FIG. 21B.

FIG. 22A is a vertical cross-sectional view of the second exemplary structure along a cut plane that corresponds to the cut plane A-A′ in FIG. 13B after bonding to a logic die according to an embodiment of the present disclosure.

FIG. 22B is a vertical cross-sectional view of the second exemplary structure along a cut plane that corresponds to the cut plane C-C′ in FIG. 13B at the processing step of FIG. 22A according to an embodiment of the present disclosure.

FIG. 23A is a vertical cross-sectional view of a semiconductor structure having a first capacitor connection configuration according to an embodiment of the present disclosure.

FIG. 23B is a vertical cross-sectional view of a semiconductor structure having a second capacitor connection configuration according to an embodiment of the present disclosure.

FIG. 23C is a vertical cross-sectional view of a semiconductor structure having a third capacitor connection configuration according to an embodiment of the present disclosure.

FIG. 24 is an exemplary layout that may be employed in the first and second exemplary structures according to embodiments of the present disclosure.

### DETAILED DESCRIPTION

As discussed above, the embodiments of the present disclosure are directed to a three-dimensional memory device containing capacitors which are located in a dummy memory block and which utilize dummy word lines as capacitor electrodes, and methods for forming the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function.

Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, removal of a first material is “selective to” a second material if the removal rate of the first material is greater than the removal rate of the second material at least by a factor of 3. Unless otherwise expressly indicated, removal of the first material selectively to the second material implies the possibility of the ratio of the removal rates equal to, or greater than, 3, and/or 10, and/or 100, and/or 1,000.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

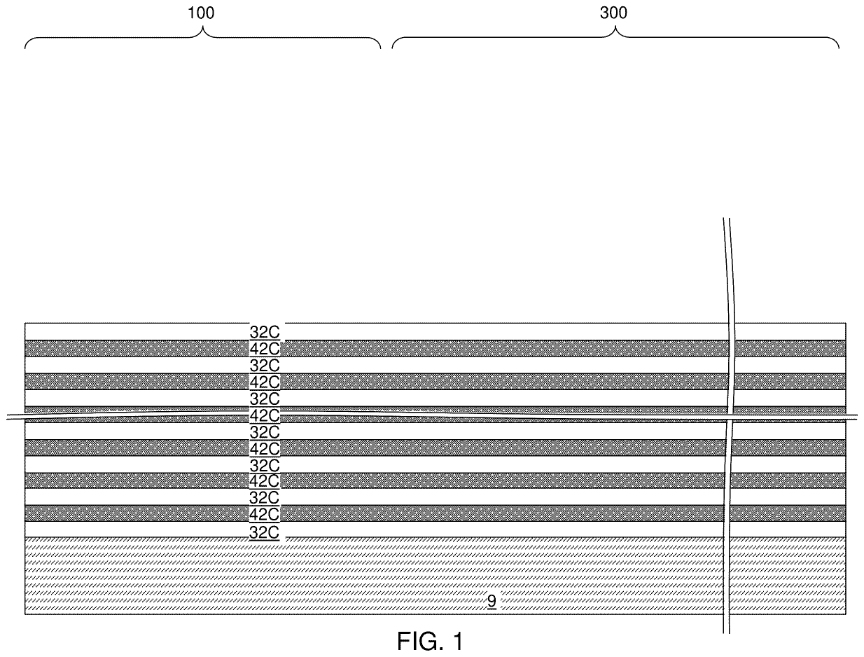

Referring to FIG. 1, a first exemplary structure according to an embodiment of the present disclosure is illustrated. The first exemplary structure comprises a carrier substrate 9, which may be a semiconductor substrate, an insulating substrate, a conductive substrate, or a composite substrate including a layer stack of at least two different material layers. For example, the carrier substrate 9 may comprise a commercially available silicon wafer. Alternatively, the carrier substrate 9 may comprise any material that may be removed selectively to the materials of continuous insulating layers 32C and dielectric material portions to be subsequently formed.

A vertically alternating sequence of first material layers and second material layers can be formed over the carrier substrate 9. The first material layers may be continuous insulating layers, and the second material layers may be spacer material layers. In one embodiment, the spacer material layers may comprise continuous sacrificial material layers 42C. In this case, a vertically alternating sequence (32C, 42C) of continuous insulating layers 32C and continuous sacrificial material layers 42C can be formed over the carrier substrate 9. Each continuous insulating layer 32C may continuously extend over the entire area of the carrier substrate 9, and each continuous sacrificial material layer 42C may continuously extend over the entire area of the carrier substrate 9. The continuous insulating layers 32C comprise an insulating material such as undoped silicate glass or a doped silicate glass, and the continuous sacrificial material layers 42C comprise a sacrificial material such as silicon nitride or a silicon-germanium alloy. In one embodiment, the continuous insulating layers 32C (i.e., the first material layers) may comprise silicon oxide layers, and the continuous sacrificial material layers 42C (i.e., the second material layers) may comprise silicon nitride layers.

The vertically alternating sequence (32C, 42C) may comprise multiple repetitions of a unit layer stack including an continuous insulating layer 32C and a continuous sacrificial material layer 42C. The total number of repetitions of the unit layer stack within the vertically alternating sequence (32C, 42C) may be, for example, in a range from 8 to 1,024, such as from 32 to 256, although lesser or greater number of repetitions may also be employed. The topmost one of the continuous insulating layers 32C is hereafter referred to as a topmost continuous insulating layer 32C. The bottommost one of the continuous insulating layers 32C is an continuous insulating layer 32C that is most proximal to the carrier substrate 9 is herein referred to as a bottommost continuous insulating layer 32C.

Each of the continuous insulating layers 32C other than the topmost continuous insulating layer 32C may have a thickness in a range from 20 nm to 100 nm, such as from 30 nm to 60 nm, although lesser or greater thicknesses may also be employed. Each of the continuous sacrificial material layers 42C may have a thickness in a range from 20 nm to 100 nm, such as from 30 nm to 60 nm, although lesser or greater thicknesses may also be employed. In one embodiment, the topmost continuous insulating layer 32C may have a thickness of about one half of the thickness of other continuous insulating layers 32C.

The first exemplary structure comprises full-stack regions 100 in which a three-dimensional array of memory elements is to be subsequently formed, and staircase regions 300 in which layer contact via structures and electrode contact via structures are to be subsequently formed.

While an embodiment is described in which the spacer material layers are formed as continuous sacrificial material layers 42C, the spacer material layers may be formed as electrically conductive layers in an alternative embodiment. Generally, spacer material layers of the present disclosure may be formed as, or may be subsequently replaced at least partly with, electrically conductive layers.

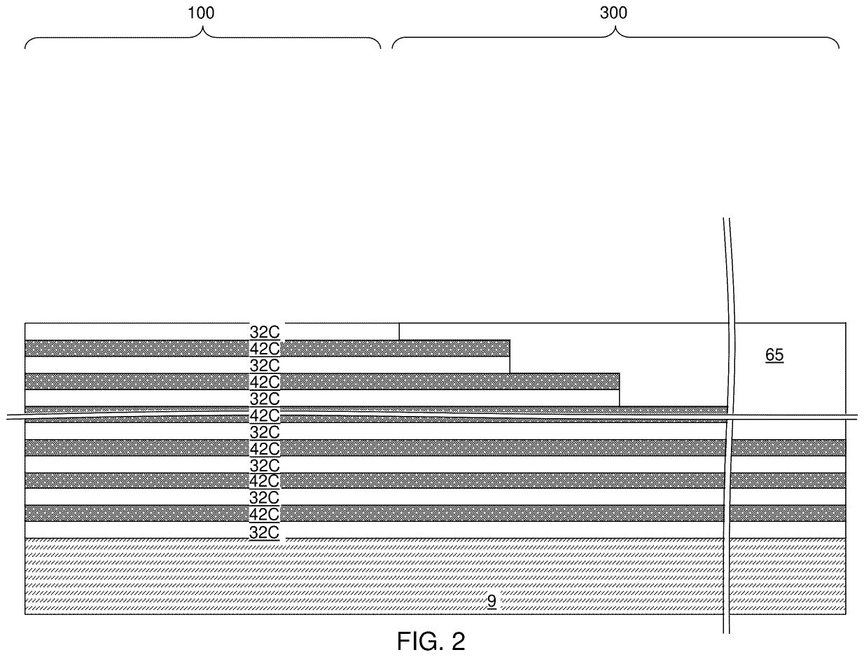

Referring to FIG. 2, stepped surfaces are formed in the staircase regions 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the vertically alternating sequence (32C, 42C) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure. In one embodiment, the topmost vertical step of the stepped surfaces may be formed in a vertical Euclidian plane, i.e., a vertical plane that is free of any curvature.

In one embodiment, each continuous sacrificial material layer 42C other than a topmost continuous sacrificial material layer 42C within the vertically alternating sequence (32C, 42C) laterally extends farther than any overlying continuous sacrificial material layer 42C within the vertically alternating sequence (32C, 42C) in the staircase regions 300. The stepped surfaces of the vertically alternating sequence (32C, 42C) continuously extend from a bottommost layer within the vertically alternating sequence (32C, 42C) to a topmost layer within the vertically alternating sequence (32C, 42C). a retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost continuous insulating layer 32C, for example, by chemical mechanical planarization (CMP). The remaining portion of the deposited dielectric material filling the stepped cavity constitutes the retro-stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

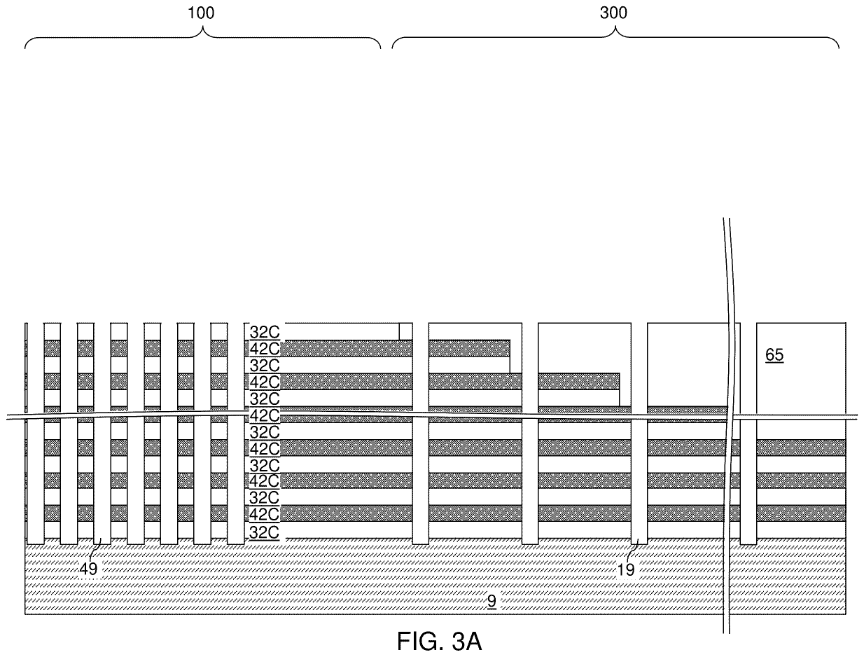

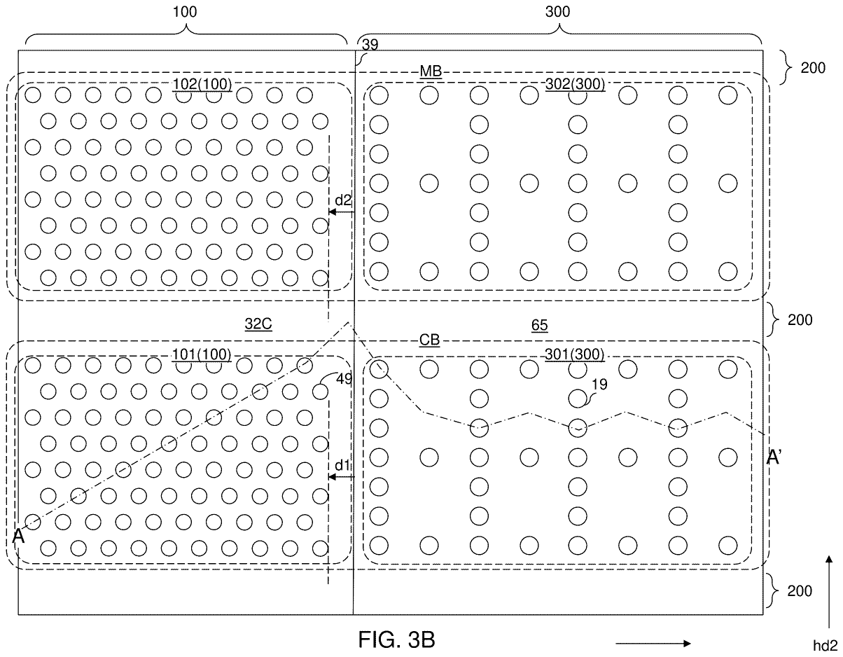

Referring to FIGS. 3A and 3B, an etch mask layer (such as a photoresist layer) can be formed over the vertically alternating sequence (32C, 42C), and can be lithographically patterned to form openings in the full-stack regions 100 and in the staircase regions 300. An anisotropic etch process can be performed to transfer the pattern of the openings in the etch mask layer through the retro-stepped dielectric material portion 65 and the vertically alternating sequence (32C, 42C). Memory openings 49 are formed through the vertically alternating sequence (32C, 42C) in the full-stack regions 100. Support openings 19 can optionally be formed through the retro-stepped dielectric material portion 65 and the vertically alternating sequence (32C, 42C) in the staircase regions 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser or greater thicknesses may be employed. The support openings 19 may have a diameter in a range from 60 nm to 400 nm, such as from 120 nm to 300 nm, although lesser or greater thicknesses may be employed. Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (e.g., the word line direction) with a uniform pitch. The rows of memory openings 49 may be laterally spaced from each other along the second horizontal direction hd2 (e.g., the bit line direction), which may be perpendicular to the first horizontal direction hd1. In one embodiment, each cluster of memory openings 49 may be formed as a two-dimensional periodic array of memory openings 49.

In one embodiment illustrated in FIG. 3B, the vertical steps of the stepped surfaces in the staircase regions 300 may be perpendicular to the first horizontal direction (e.g., word line direction) hd1. The topmost vertical step of the stepped surfaces in the staircase regions 300 defines the boundary 39 between the staircase regions 300 and the full-stack regions 100. Clusters of memory openings 49 and support openings 19 may be laterally spaced apart from each other along elongated gap regions 200 that laterally extend along the first horizontal direction hd1 across the boundary 39. Each cluster of memory openings 49 may be formed within a respective full-stack region 100. Each cluster of support openings 19 may be formed within a respective staircase region 300. Thus, a pair of a full-stack region 100 and a staircase region 300 may be provided between each neighboring pair of elongated gap regions 200 that laterally extend along the first horizontal direction hd1 with a respective substantially uniform width along the second horizontal direction (e.g., bit line directions) hd2. Each pair of a full-stack region 100 and a staircase region 300 constitutes a region for forming a respective block, which may be a capacitor block (e.g., a dummy memory block) CB or a memory block (e.g., an active memory block) MB.

According to an aspect of the present disclosure, a first pair of a first full-stack region 101 and a first staircase region 301 constitutes a capacitor block CB in which capacitor structures are to be subsequently formed. A second pair of a second full-stack region 102 and a second staircase region 302 constitutes a memory block MB in which a three-dimensional memory array is to be subsequently formed. In one embodiment, multiple capacitor blocks CB and multiple memory blocks MB may be repeated along the second horizontal direction hd2. The total number of the blocks of each type and the relative order of the multiple capacitor blocks CB and multiple memory blocks MB may be selected in any combination.

In one embodiment, the memory openings 49 in each full-stack region 100 may be arranged as multiple rows of memory openings 49 such that each row of memory openings 49 includes a one-dimensional periodic array of memory openings 49 arranged along the first horizontal direction hd1, and the multiple rows are laterally spaced apart from each other along the second horizontal direction hd2. In one embodiment, the memory openings 49 in each full-stack region 100 may be arranged as a two-dimensional periodic array, such as a hexagonal periodic array, having the first horizontal direction hd1 as a direction of periodicity. In one embodiment, the most proximal memory openings 49 within the first full-stack region 101 may be laterally spaced from the vertical plane (i.e., the boundary 39) including the topmost vertical step of the stepped surfaces in the staircase regions 300 by a first distance d1, and the most proximal memory openings 49 within the second full-stack region 102 may be laterally spaced from the vertical plane (i.e., the boundary 39) including the topmost vertical step of the stepped surfaces in the staircase regions 300 by a second distance d2. According to an aspect of the present disclosure, the first distance d1 is not less than the second distance d2, and may be the same as the second distance d2.

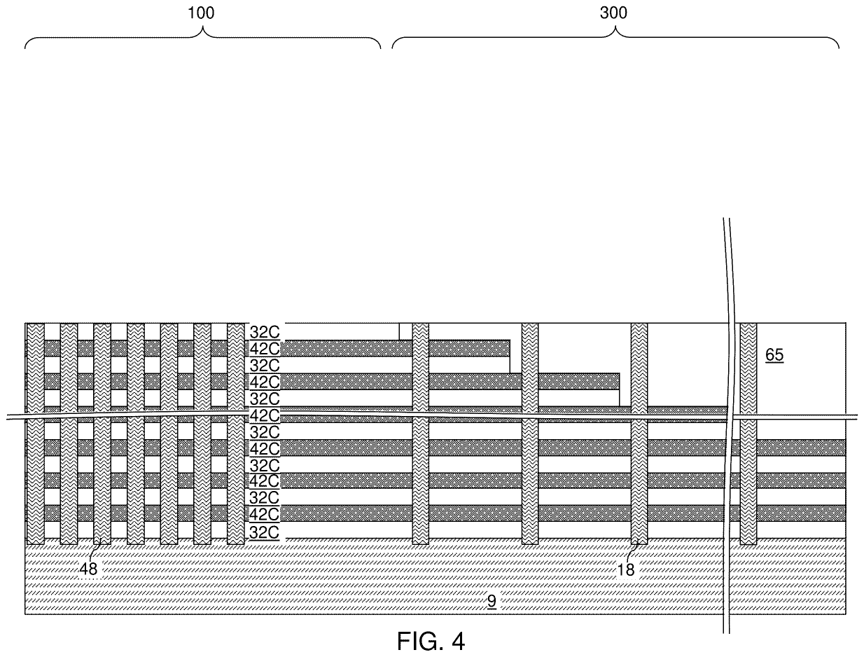

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost continuous insulating layer 32C. Each remaining portion of the sacrificial fill material that fills a memory opening 49 constitutes a sacrificial memory opening fill structure 48. Each remaining portion of the sacrificial fill material that fill a support opening 19 constitutes a sacrificial support opening fill structure 18.

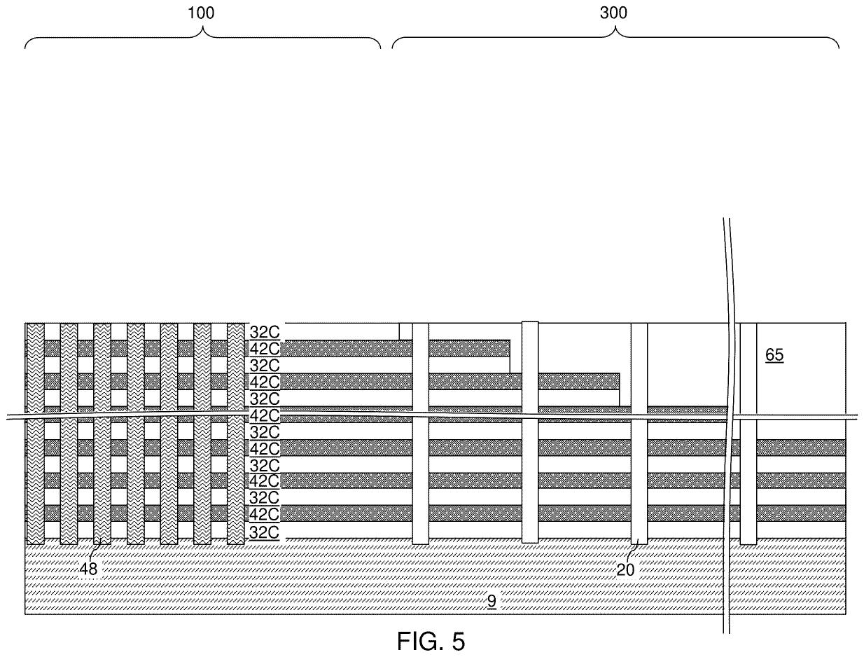

Referring to FIG. 5, a photoresist layer (not shown) can be applied over the first exemplary structure, and can be lithographically patterned to cover the sacrificial memory opening fill structures 48 in the full-stack regions 100 without covering the sacrificial support opening fill structures 18 in the staircase regions 300. The sacrificial support opening fill structures 18 are subsequently removed selectively to the materials of the continuous insulating layers 32C, the continuous sacrificial material layers 42C, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost continuous insulating layer 32C, for example, by a recess etch process. Each portion of the dielectric fill material that fills a respective support opening 19 constitutes a support pillar structure 20, which can be employed to provide structural support to the continuous insulating layers 32C and the retro-stepped dielectric material portion 65 during replacement of the continuous sacrificial material layers 42C with electrically conductive layers. In an alternative embodiment, the processing steps described with reference to FIG. 5 may be omitted, and the sacrificial support opening fill structures 18 can be removed at a later step during which the sacrificial memory opening fill structures 48 are removed. In this case, support pillar structures having a same set of materials as memory opening fill structures can be formed in the support openings 19 during a set of processing steps that forms the memory opening fill structures.

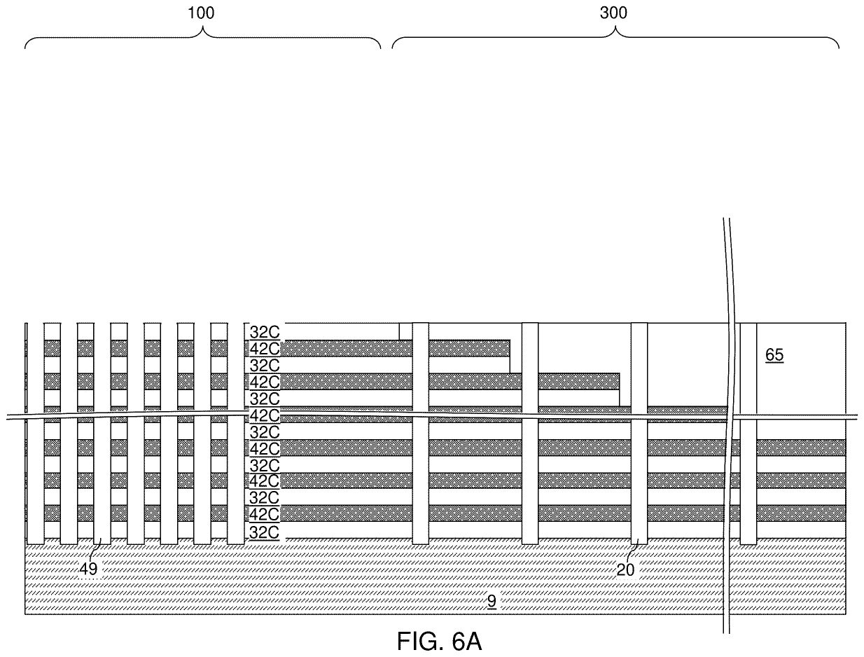

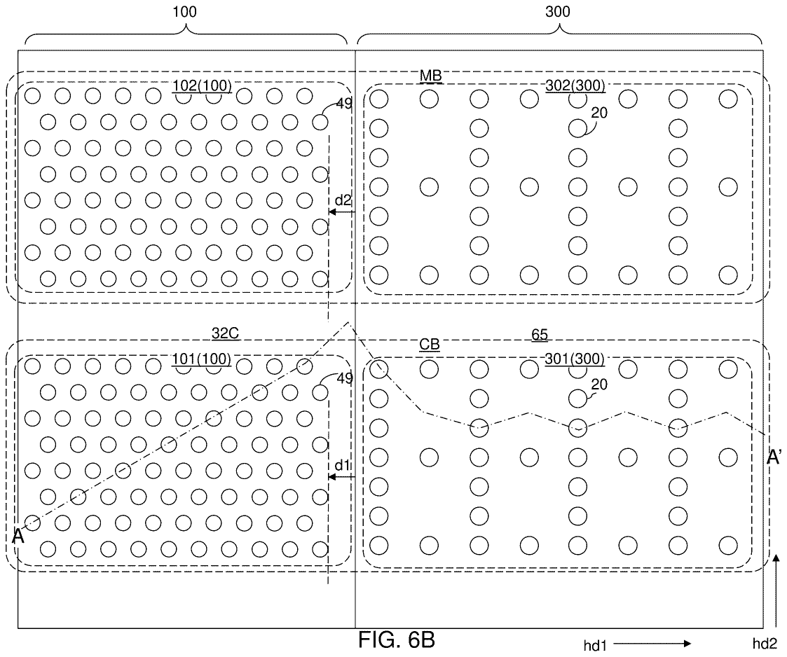

Referring to FIG. 6, sacrificial memory opening fill structures 48 are subsequently removed selectively to the materials of the continuous insulating layers 32C, the continuous sacrificial material layers 42C, and the carrier substrate 9. Voids are formed in the volumes of the memory openings 49 from which the sacrificial memory opening fill structures 48 are removed.

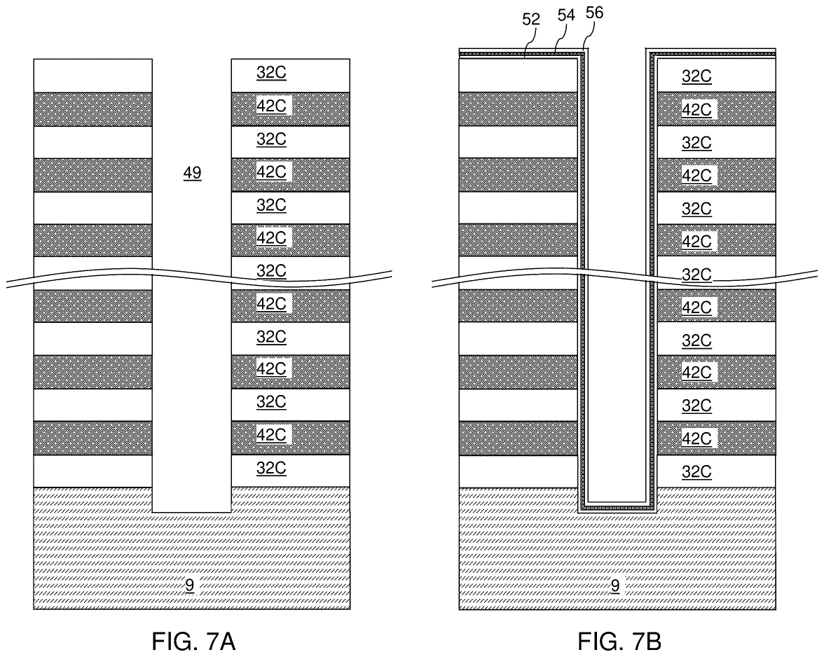

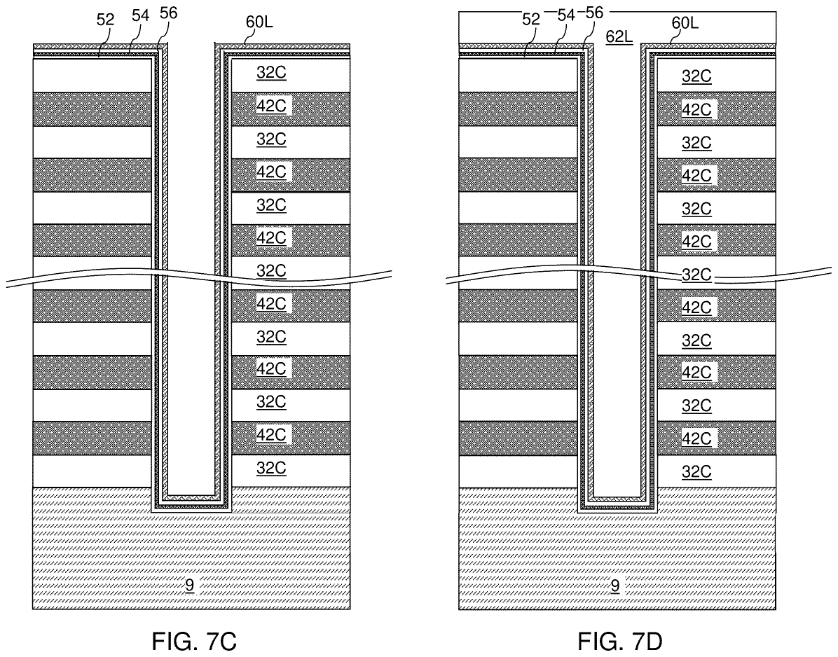

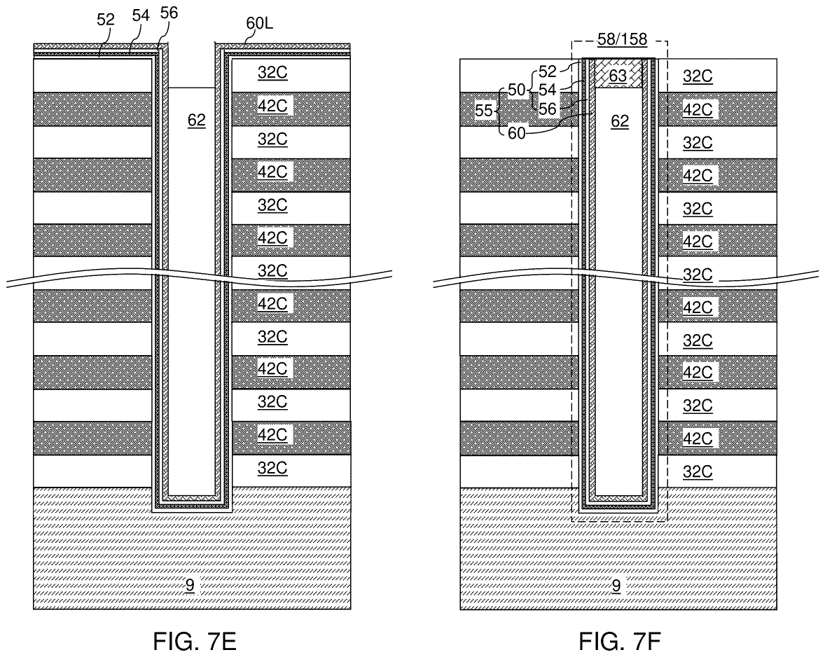

FIG. 7A-7F are sequential vertical cross-sectional views of a memory opening 49 during formation of a memory opening fill structure 58 or a dummy memory opening fill structure 158 according to an embodiments of the present disclosure. The memory opening fill structures 58 are formed in the memory openings 49 in a respective second full-stack region 102 of the memory block MB, and the dummy memory opening fill structures 158 are formed in the memory openings 49 in a respective first full-stack region 101 of the capacitor block CB.

Referring to FIG. 7A, a memory opening 49 is illustrated after the processing steps of FIG. 6. Generally, a vertically alternating sequence of continuous insulating layers 32C and spacer material layers (which may comprise the continuous sacrificial material layers 42C) can be formed over a carrier substrate 9. The spacer material layers are formed as, or are subsequently replaced with, electrically conductive layers. The memory openings 49 are formed through the vertically alternating sequence, and may extend to or below a top surface of the carrier substrate 9.

Referring to FIG. 7B, a layer stack including a blocking dielectric layer 52, a memory material layer 54, and a tunneling dielectric layer 56 can be sequentially deposited in the memory opening 49. The blocking dielectric layer 52 can be deposited by performing a conformal deposition process. The blocking dielectric layer 52 may comprise silicon oxide, silicon oxynitride, and/or at least one dielectric metal oxide such as aluminum oxide and/or at least one transition metal oxide. The blocking dielectric layer 52 may be deposited with a uniform thickness, which may be in a range from 5 nm to 20 nm, such as from 7 nm to 10 nm, although lesser or greater thicknesses may also be employed.

The memory material layer 54 includes a memory material, i.e., a material that can store data bits therein. In one embodiment, the memory material layer 54 may comprise, and/or may consist essentially of, a charge storage material, such as silicon nitride. The memory material layer 54 may be deposited by a conformal deposition process such as a chemical vapor deposition process. The thickness of the memory material layer 54 may be in a range from 3 nm to 10 nm, such as from 4 nm to 8 nm, although lesser or greater thicknesses may also be employed.

The tunneling dielectric layer 56 can be deposited on the memory material layer 54. The tunneling dielectric layer 56 may comprise any tunneling dielectric material known in the art. For example, the tunneling dielectric layer 56 may comprise an ONO stack (i.e., a layer stack including a first silicon oxide layer, a silicon nitride layer, and a second silicon nitride layer) having a thickness in a range from 2 nm to 3 nm, although lesser or greater thicknesses may also be employed.

Referring to FIG. 7C, the semiconductor channel material layer 60L can be deposited over the memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser or greater thicknesses may also be employed. In one embodiment, the semiconductor channel material layer 60L includes first electrical dopants of a first conductivity type at a first atomic concentration, which may be in a range from 1.0×10¹³/cm³ to 1.0×10¹⁶/cm³, although lesser or greater atomic concentrations may also be employed.

Referring to FIG. 7D, a dielectric core layer 62L comprising a dielectric fill material, such as silicon oxide, can be deposited in remaining volumes of the memory openings 49.

Referring to FIG. 7E, the dielectric core layer 62L can be subsequently vertically recessed such that each remaining portion of the dielectric core layer has a top surface at, or about, the horizontal plane including the bottom surface of the topmost continuous insulating layer 32C. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser or greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost continuous insulating layer 32C, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60. In one embodiment, each vertical semiconductor channel 60 includes first electrical dopants of a first conductivity type at the first atomic concentration. Alternatively, the vertical semiconductor channel 60 may be undoped (i.e., intrinsic).

Each portion of the layer stack including the memory material layer 54 that remains in a respective memory opening 49 constitutes a memory film 50. In one embodiment, a memory film 50 may comprise a blocking dielectric layer stack including a blocking dielectric layer 52; a memory material layer 54; and a tunneling dielectric layer 56. Each contiguous combination of a memory film 50 and a vertical semiconductor channel 60 constitutes a memory stack structure 55. Each combination of a memory stack structure 55, a dielectric core 62, and a drain region 63 within a memory opening 49 in a second full-stack region 102 constitutes a memory opening fill structure 58. Each combination of a memory stack structure 55, a dielectric core 62, and a drain region 63 within a memory opening 49 in a first full-stack region 101 constitutes a dummy memory opening fill structure 158.

Each memory opening fill structure 58 and each dummy memory opening fill structure 158 can be formed in a respective memory opening 49 by sequentially forming the blocking dielectric layer 52, the memory material layer 54, a tunneling dielectric layer 56, and the vertical semiconductor channel 60. Each memory opening fill structure 58 and each dummy memory opening fill structure 158 can comprise a respective vertical stack of memory elements, which may comprise portions of the memory material layer 54 located at levels of the continuous sacrificial material layers 42C, or generally speaking, at levels of spacer material layers that may be formed as, or may be subsequently replaced at least partly with, electrically conductive layers.

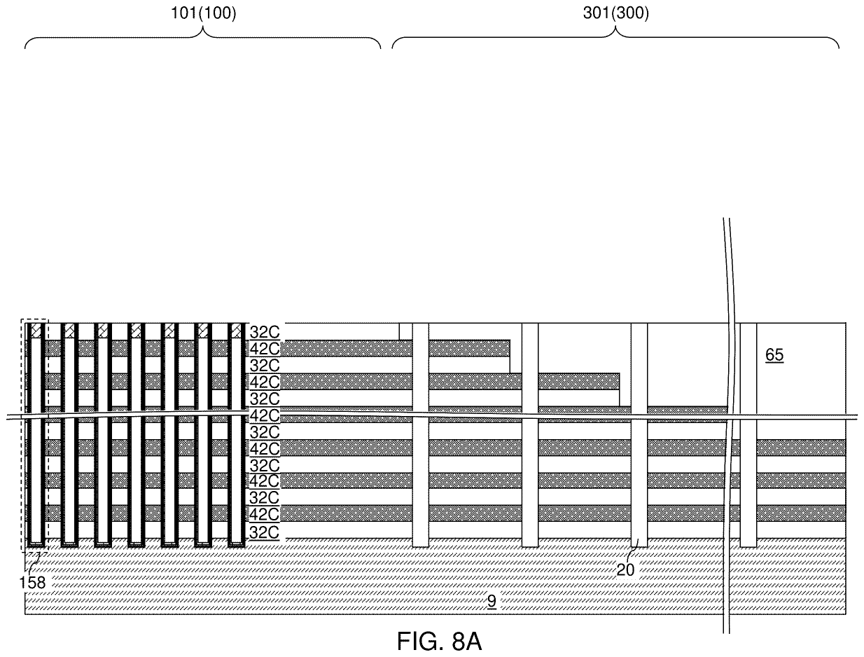

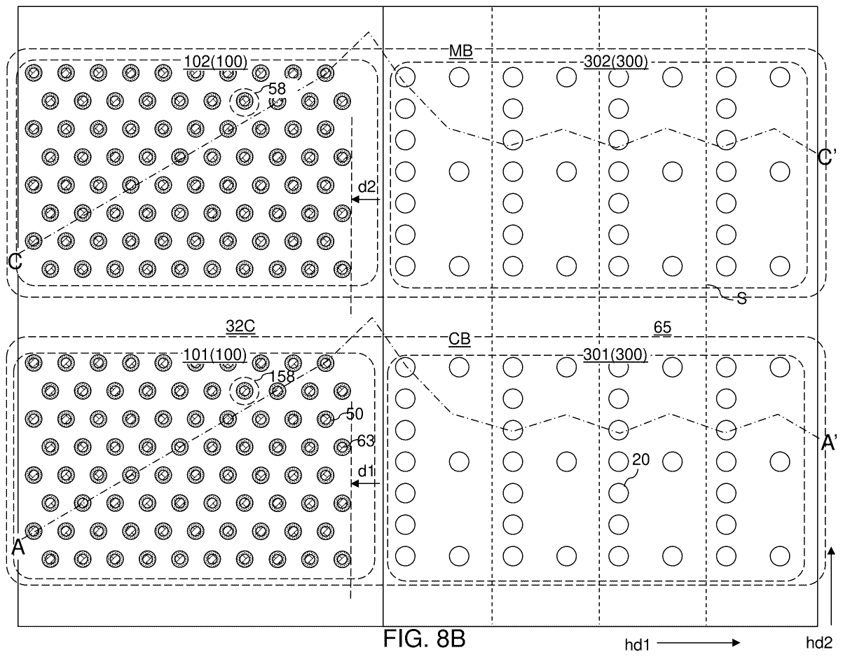

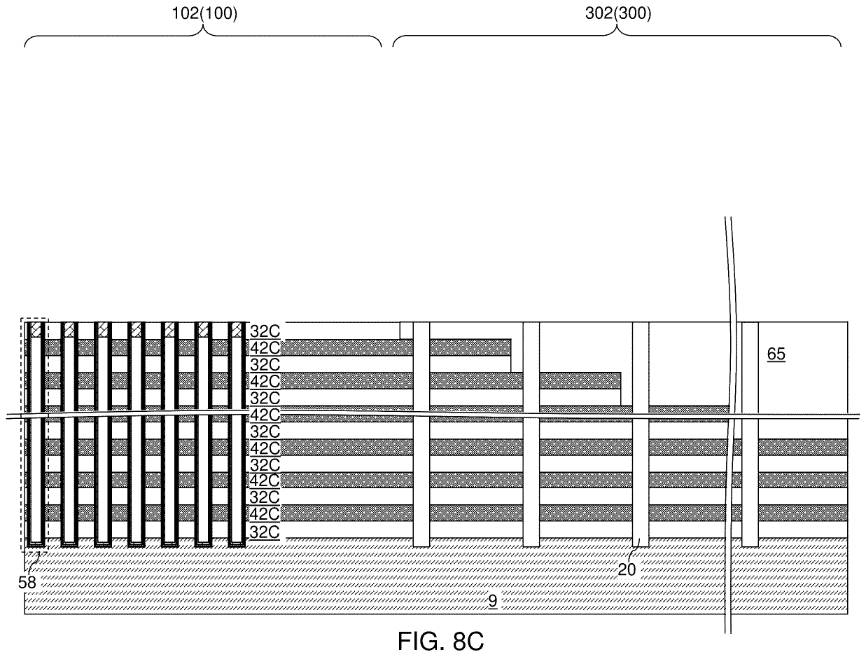

Referring to FIGS. 8A-8C, the first exemplary structure is illustrated after formation of memory opening fill structures 58 and the dummy memory opening fill structures 158 within the memory openings 49. The memory opening fill structures 58 are located in a subset of the memory openings 49 located in the second full-stack regions 102. Each of the memory opening fill structures 58 comprises a respective memory film 50 and a respective vertical semiconductor channel 60. The dummy memory opening fill structures 158 are located in a subset of the memory openings 49 located in the first full-stack regions 101. Each of the dummy memory opening fill structures 158 comprises a respective memory film 50 and a respective vertical semiconductor channel 60.

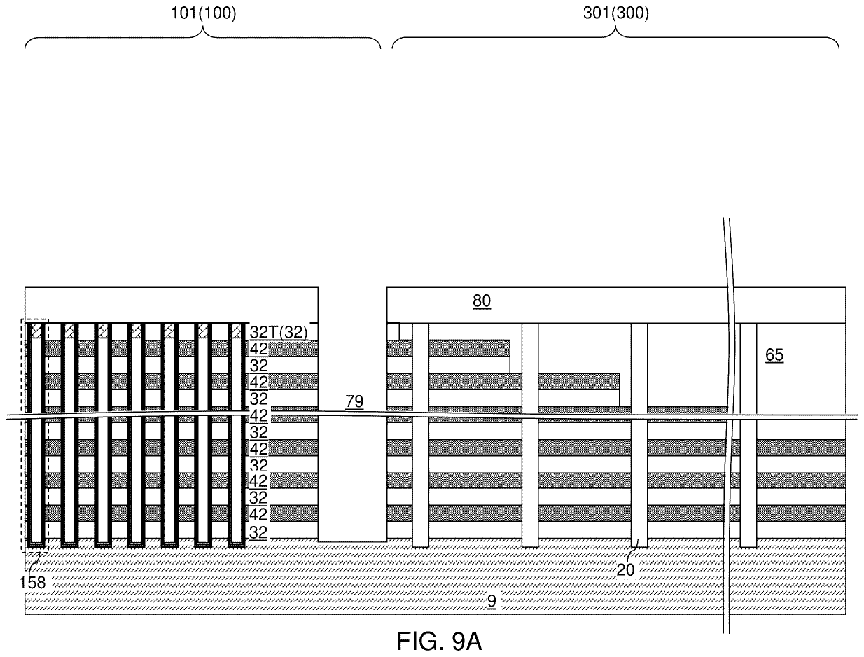

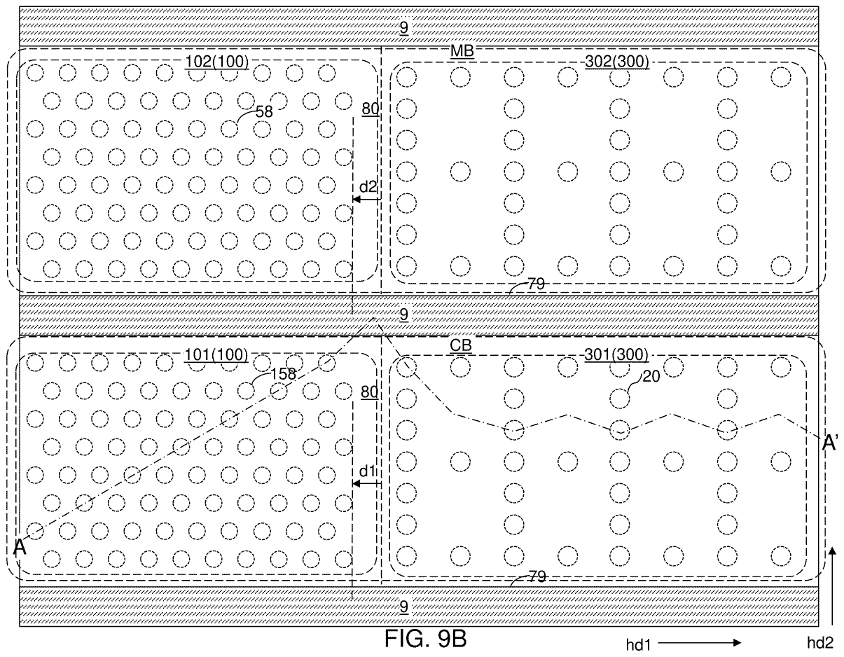

Referring to FIGS. 9A and 9B, a dielectric material, such as undoped silicate glass (i.e., silicon oxide) or a doped silicate glass can be deposited over the vertically alternating sequence (32C, 42C) to form a contact-level dielectric layer 80. The thickness of the contact-level dielectric layer 80 may be in a range from 100 nm to 600 nm, such as from 200 nm to 400 nm, although lesser or greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the vertically alternating sequence (32C, 42C), and the retro-stepped dielectric material portion 65, and to a top surface of the carrier substrate 9. Lateral isolation trenches 79 laterally extending along the first horizontal direction hd1 can be formed through the vertically alternating sequence (32C, 42C), the retro-stepped dielectric material portion 65, and the contact-level dielectric layer 80. The lateral isolation trenches 79 can be formed in a respective elongated gap region 200 located between neighboring pairs of blocks (MB, CB). Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

The vertically alternating sequence (32C, 42C) can be divided into multiple discrete material layer stacks that are laterally spaced apart from each other by the lateral isolation trenches 79. Each patterned portion of a continuous insulating layer 32C is herein referred to as an insulating layer 32. Each patterned portion of a continuous sacrificial material layer 42C is herein referred to as a sacrificial material layer 42. A first alternating stack (32, 42) of first insulating layers 32 and first sacrificial material layers 42 can be formed in each capacitor block CB. A second alternating stack (32, 42) of second insulating layers 32 and second sacrificial material layers 42 can be formed in each memory block MB. Each second alternating stack (32, 42) may embed a respective two-dimensional array of memory opening fill structures 58. Each first alternating stack (32, 42) may embed a respective two-dimensional array of dummy memory opening fill structures 158. Each alternating stack (32, 42) may comprise a respective topmost insulating layer 32T, which is the topmost one of all insulating layers 32 within the respective alternating stack (32, 42).

The retro-stepped dielectric material portion 65 is divided into a plurality of retro-stepped dielectric material portions 65. In one embodiment, an array of dummy memory opening fill structures 158 can be provided in each first full-stack region 101, and an array of memory opening fill structures 58 can be provided in each second full-stack region 102. In one embodiment, the array of dummy memory opening fill structures 158 within each first full-stack region 101 may be laterally spaced from the vertical plane including the topmost vertical step of the stepped surfaces in the first staircase regions 301 in the same capacitor block CB by the first distance d1. The array of memory opening fill structures 58 within each second full-stack region 102 may be laterally spaced from the vertical plane including the topmost vertical step of the stepped surfaces in the second staircase regions 302 in the same memory block MB by the second distance d2. According to an aspect of the present disclosure, the first distance d1 is not less than the second distance d2, and may be the same as the second distance d2.

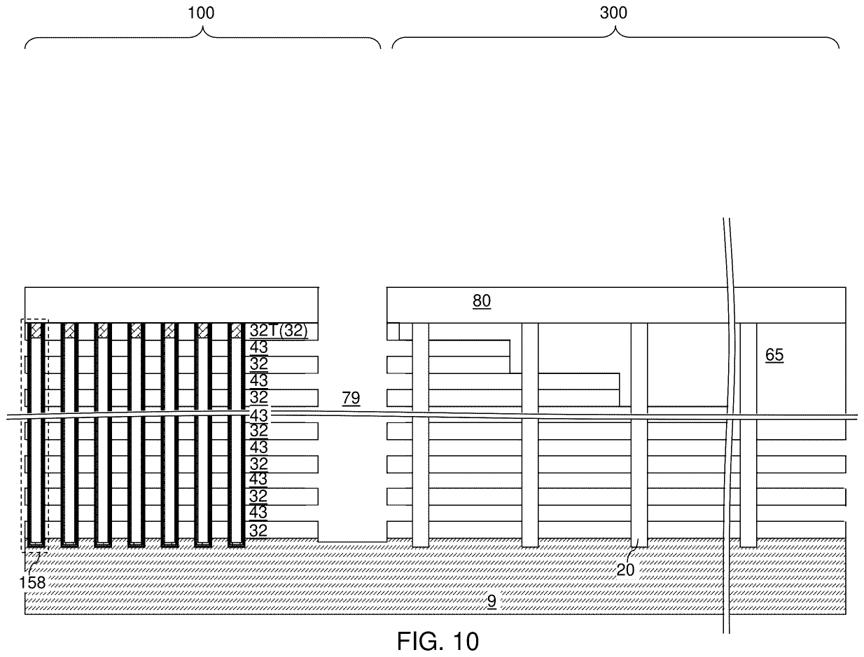

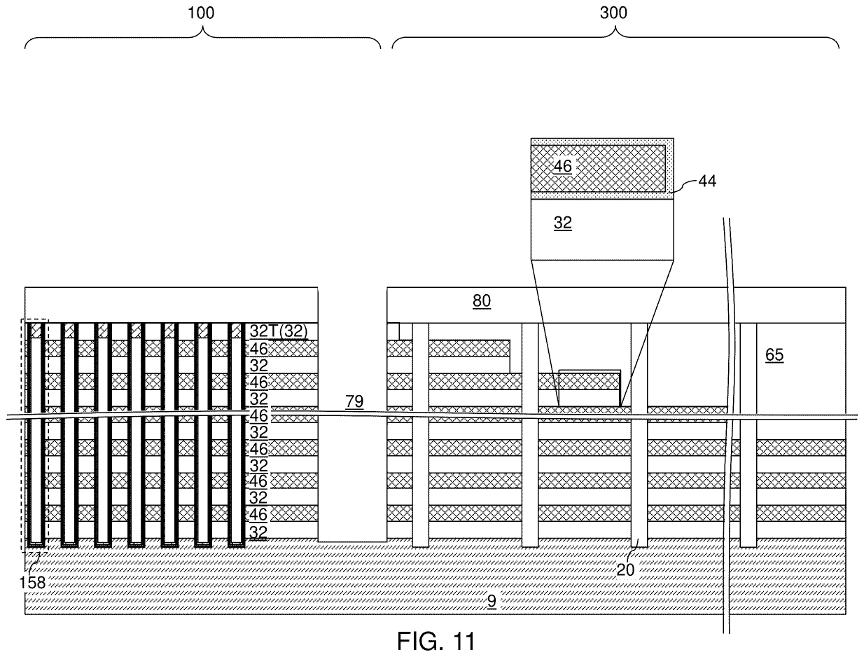

Referring to FIG. 10, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the retro-stepped dielectric material portion 65, and the material of the outermost layer of the memory films 50. In one embodiment, the sacrificial material layers 42 can include silicon nitride, and the materials of the insulating layers 32 and the retro-stepped dielectric material portion 65 can include silicon oxide.

The etch process that removes the second material selectively to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selectively to silicon oxide, silicon, and various other materials employed in the art. The support pillar structure 20, the retro-stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

Referring to FIG. 11, an outer blocking dielectric layer 44 can be optionally deposited by performing a conformal deposition process. In one embodiment, the outer blocking dielectric layer 44 comprises and/or consists essentially of aluminum oxide. The outer blocking dielectric layer 44 may be formed by a conformal deposition process, such as an atomic layer deposition process. The thickness of the outer blocking dielectric layer 44 may be in a range from 2 nm to 4 nm, although lesser or greater thicknesses may also be employed.

At least one conductive material can be deposited in the lateral recesses 43 by providing at least one reactant gas into the lateral recesses 43 through the lateral isolation trenches 79. For example, a combination of a metallic barrier layer and a metal fill material may be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser or greater thicknesses can also be employed. In one embodiment, the metallic barrier layer can consist essentially of a conductive metal nitride such as TiN.

The metal fill material can be deposited in remaining volumes of the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer (not shown) can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

In one embodiment, each of the electrically conductive layers 46 may be formed between a respective vertically neighboring pair of the insulating layers 32 of the alternating stack (32, 46). Each vertically neighboring pair of insulating layers 32 includes a respective overlying insulating layer 32 and a respective underlying insulating layer 32. Portions of the outer blocking dielectric layer 44 in the lateral isolation trenches 79 or over the contact-level dielectric layer 80 may be removed employing a recess etch process. In this case, for each electrically conductive layer 46 that is formed between a respective vertically neighboring pair of insulating layers 32 (i.e., an overlying insulating layer 32 and an underlying insulating layer 32, a respective outer blocking dielectric layer 44 may be located entirely below a horizontal plane including a bottom surface of the overlying insulating layer 32 and entirely above a horizontal plane including a top surface of the underlying insulating layer 32.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

The first exemplary structure comprises a first alternating stack (32, 46) of first insulating layers 32 and first electrically conductive layers 46 that alternate along a vertical direction. The first alternating stack (32, 46) includes a first staircase region 301 containing first stepped surfaces and a first full-stack region 101 where each layer within the first alternating stack (32, 46) is present. First openings (such as a subset of the memory openings 49) extend vertically through each of the first insulating layers 32 and each of the first electrically conductive layers 46 in the first full-stack region 101. First opening fill structures fill the first openings. The first opening fill structures may be dummy memory opening fill structures 158. In one embodiment, the dummy memory opening fill structures 158 may include a vertical semiconductor channel 60, a drain region 63, and a vertical stack of memory elements, which may comprise portions of a memory material layer 54.

A contact-level dielectric layer 80 overlies the first alternating stack (32, 46). The entirety of the top surfaces of the first opening fill structures (such as the dummy memory opening fill structures 158) may be in contact with the dielectric material of the contact-level dielectric layer 80. A first retro-stepped dielectric material portion 65 overlies the first stepped surfaces in the first staircase region 301. Lateral isolation trenches 79 may be present, which laterally extend along a first horizontal direction hd1 and may have a uniform width along a second horizontal direction hd2.

A second alternating stack (32, 46) of second insulating layers 32 and second electrically conductive layers 46 is laterally spaced from the first alternating stack (32, 46) by a lateral isolation trench 79. The second alternating stack may include a second staircase region 302 containing second stepped surfaces and a second full-stack region 102. Memory opening fill structures 58 are present in the second alternating stack (32, 46). Each of the memory opening fill structures 58 comprises a vertical semiconductor channel 60, a drain region 63, and a vertical stack of memory elements (which may comprise portion of a memory material layer 54 located at the levels of the second electrically conductive layers 46). In one embodiment, each of the memory opening fill structures 58 may be identical to each of the dummy memory opening fill structures 158.

The first stepped surfaces and second stepped surfaces may extend along the first horizontal direction hd1, with vertical steps that are parallel to the second horizontal direction hd2. A minimum lateral spacing along the first horizontal direction hd1 between a topmost vertical step within the first stepped surfaces and the first opening fill structures may be a first distance d1 that is greater than zero. A minimum lateral spacing along the first horizontal direction hd1 between a topmost vertical step within the second stepped surfaces and the memory opening fill structures 58 may be a second distance d2. The first distance d1 is not less than the second distance d2, and may be the same as the second distance d1. The topmost vertical step within the first stepped surfaces and the topmost vertical step within the second stepped surfaces may be contained entirely within a vertical Euclidian plane that is perpendicular to the first horizontal direction hd1.

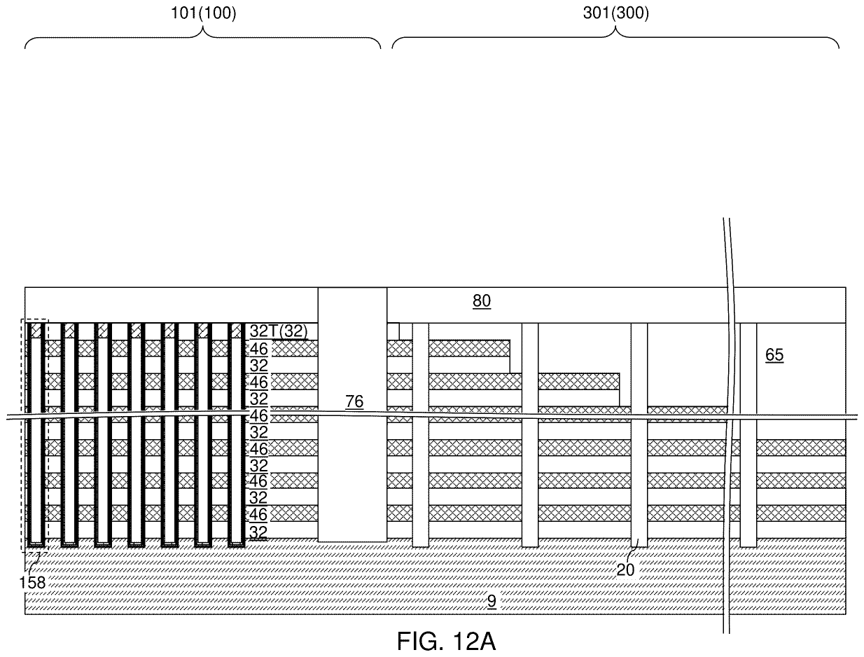

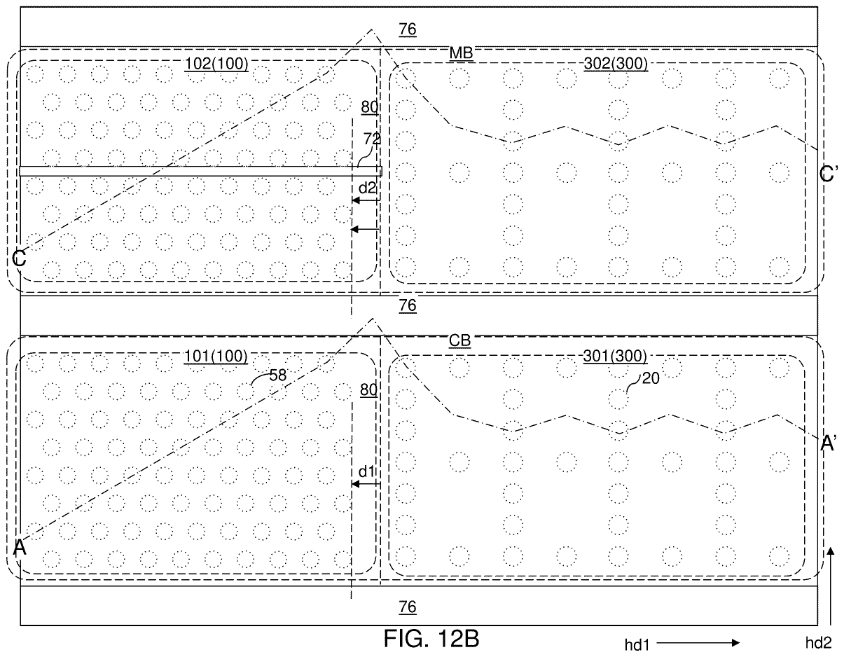

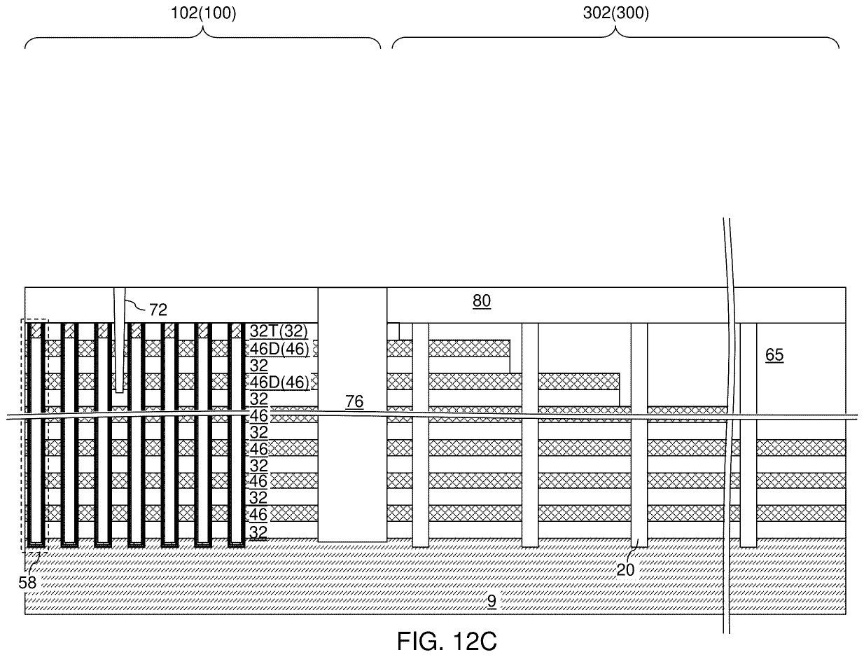

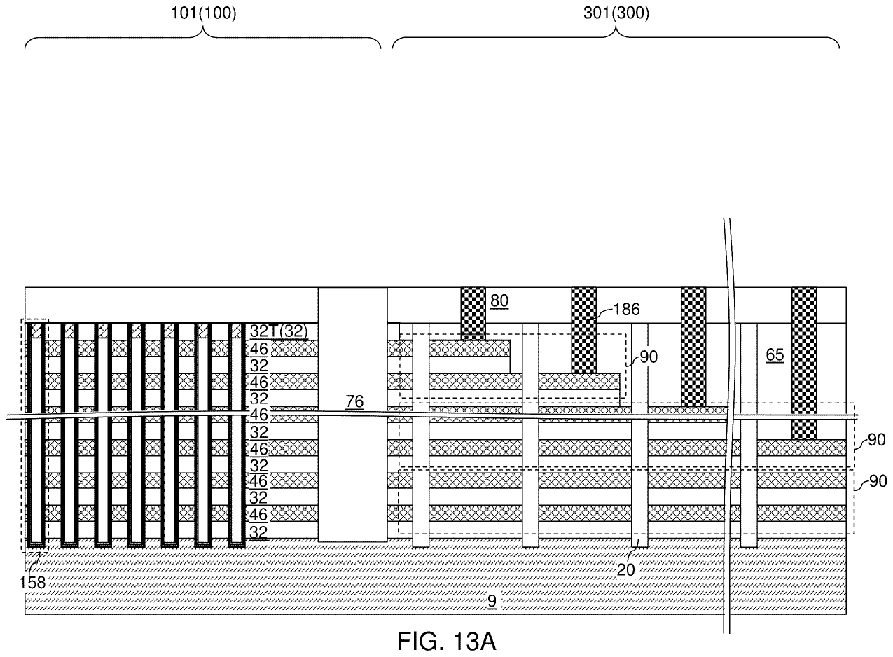

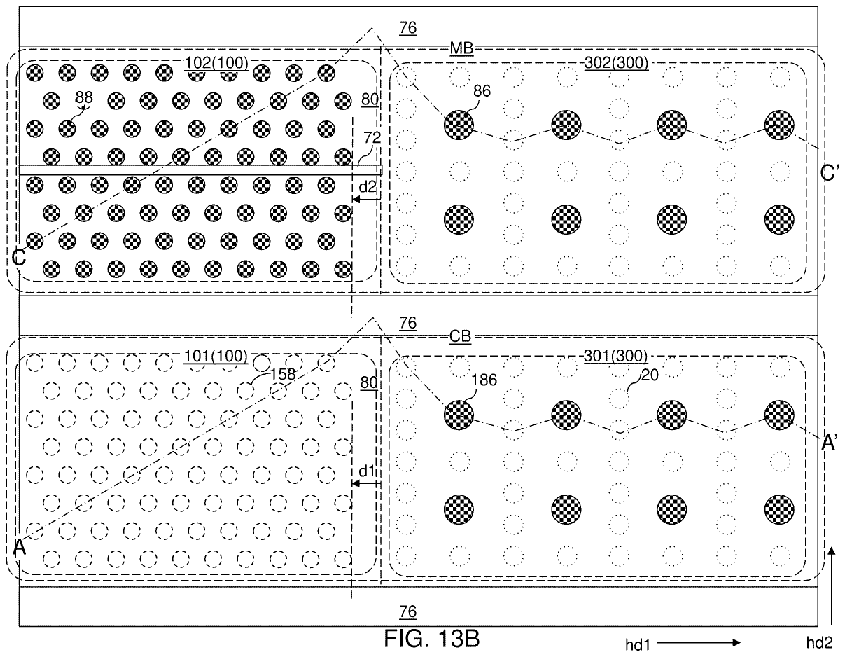

Referring to FIGS. 12A-12C, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Drain-select-level isolation structures 72 may be formed through the contact-level dielectric layer 80 and a set of at least one electrically conductive layer 46 within each second full-stack region 102 in the memory block MB. Each electrically conducive layer 46 that is divided by a respective drain-select-level isolation structure 72 is herein referred to as a drain-select-level electrically conductive layer 46D, which may function as a drain-side select electrode for a respective set of NAND strings (e.g., memory opening fill structures 58). The drain-select-level isolation structure 72 may be either present or omitted in the capacitor block CB.

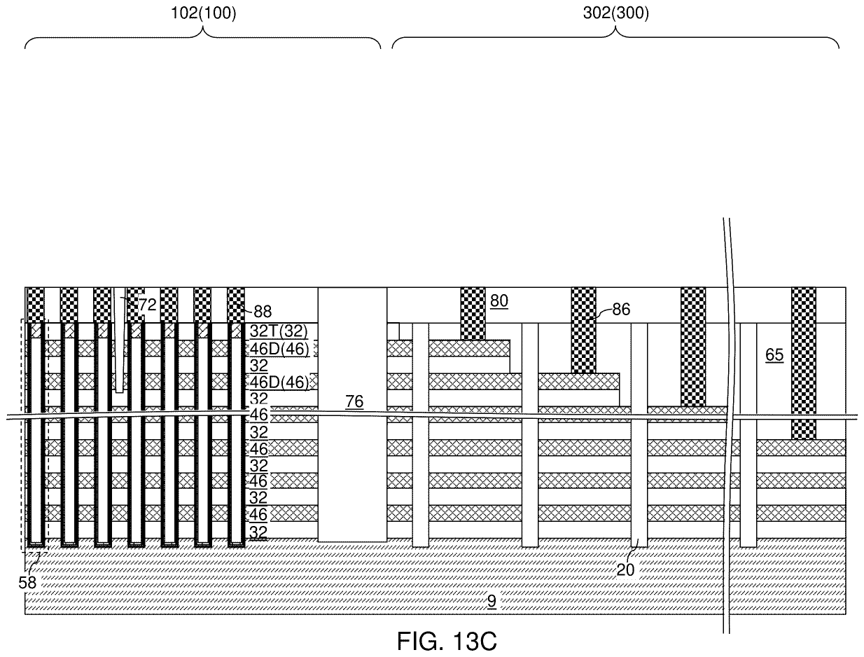

Referring to FIGS. 13A-13C, contact via structures (88, 86, 186) can be formed through the contact-level dielectric layer 80. For example, drain contact via structures 88 can be formed through the contact-level dielectric layer 80 on each drain region 63 in the memory blocks MB. In one embodiment, the drain contact via structures 88 are omitted in the capacitor blocks CB. Layer contact via structures 86 can be formed on each electrically conductive layers 46 in the memory blocks MB through the contact-level dielectric layer 80 and through a respective retro-stepped dielectric material portion 65. Electrode contact via structures 186 can be formed on each electrically conductive layers 46 in the capacitor blocks CB through the contact-level dielectric layer 80 and through a respective retro-stepped dielectric material portion 65. In one embodiment, the electrode contact via structures 186 and the layer contact via structures 86 may be formed simultaneously, and may have the same material composition. In one embodiment, the electrode contact via structures 186 and the layer contact via structures 86 may have top surfaces located within the horizontal plane including the top surface of the contact-level dielectric layer 80.

According to an aspect of the present disclosure shown in FIG. 13A, at least one pair of a first electrode contact via structure 186 and a second electrode contact via structure 186 can be provided such that the first electrode contact via structure 186 and the second electrode contact via structure 186 may contact a vertically neighboring pair of first electrically conductive layers 46 within a first alternating stack (32, 46) in the capacitor block CB to provide a capacitor structure 90. In each capacitor structure 90, an intervening first insulating layer 32 of the first insulating layers 32 that is located between the vertically neighboring pair of first electrically conductive layers 46 functions as a capacitor dielectric for the capacitor structure 90, while the vertically neighboring pair of first electrically conductive layers 46 function as capacitor electrodes.

In an alternative embodiment, plural vertically separated first insulating layers 32 may function as a capacitor dielectric, and intervening first electrically conductive layer 46 may function as a middle capacitor electrode and the overlying and underlying first electrically conductive layers may function as capacitor electrodes of a capacitor structure 90. In this alternative embodiment, the middle capacitor electrode may remain floating and not electrically contact a respective first electrode contact via structure 186.

A vertical stack of a plurality of capacitor structures 90 can be formed in each capacitor block CB that is laterally bounded by a respective neighboring pair of lateral isolation trench fill structures 76. Each capacitor structure comprises a respective vertically neighboring pair of first electrically conductive layers 46 as a first electrode and a second electrode, and a respective intervening insulating layer 32 as a portion of the capacitor dielectric. In case outer blocking dielectric layers 44 are employed, each capacitor dielectric may comprise horizontally-extending portions of two outer blocking dielectric layers 44 interposed between a respective vertically neighboring pair of first electrically conductive layers 46. Each first electrically conductive layer 46 in a capacitor structure may comprise a respective array of first openings therethrough, which may be filled with a respective array of dummy memory opening fill structures 158.

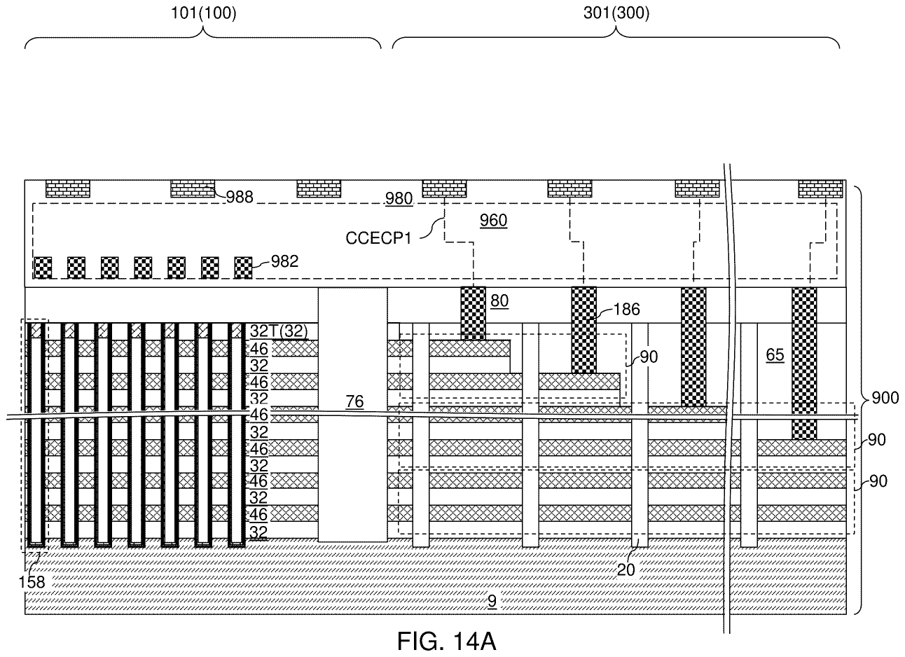

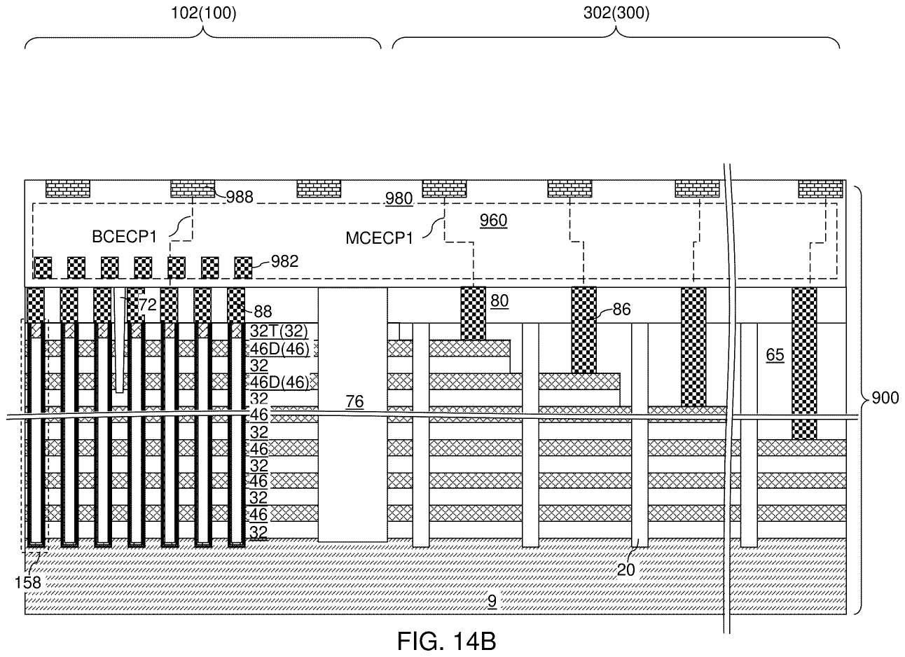

Referring to FIGS. 14A and 14B, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-die dielectric material layers 960. The additional metal interconnect structures are collectively referred to as memory-die metal interconnect structures 980. The memory-die dielectric material layers 960 comprise a bit-line-level dielectric material layer embedding bit lines 982, which are a subset of the memory-die metal interconnect structures 980.

Metal bonding pads, which are herein referred to memory-die bonding pads 988, may be formed at the topmost level of the memory-die dielectric material layers 960. The memory-die bonding pads 988 may be electrically connected to the memory-die metal interconnect structures 980 and various nodes of the three-dimensional memory array including the electrically conductive layers 46 and the memory opening fill structures 58. A memory die 900 can thus be provided.

The memory-die dielectric material layers 960 are formed over the alternating stacks (32, 46). The memory-die metal interconnect structures 980 are embedded in the memory-die dielectric material layers 960. The memory-die bonding pads 988 can be embedded within the memory-die dielectric material layers 960, and specifically, within the topmost layer among the memory-die dielectric material layers 960. The memory-die bonding pads 988 can be electrically connected to the memory-die metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60 and to a respective one of the bit lines 982.

According to an aspect of the present disclosure, a first subset of the memory-die metal interconnect structures 980 provides first capacitor connection electrically conductive paths CCECP1 between the electrode contact via structures 186 and a first subset of the memory-die bonding pads 988. A second subset of the memory-die metal interconnect structures 980 provides first memory connection electrically conductive paths MCECP1 between the layer contact via structures 86 and a second subset of the memory-die bonding pads 988. A third subset of the memory-die metal interconnect structures 980 provides first bitline connection electrically conductive paths BCECP1 between the drain contact via structures 88, the bit lines 982 and a third subset of the memory-die bonding pads 988.

The drain regions 63 of the memory opening fill structures 58 in the memory block MB are electrically connected to the bit lines 982 via the paths BCECP1. In contrast, the drain regions (e.g., dummy drain regions) 63 of the dummy memory opening fill structures 58 in the capacitor block CB are not electrically connected to the bit lines 982 via any electrically conductive path. For example, the drain contact via structures 88 between the dummy drain regions 63 and the bit lines 982 may be omitted in the capacitor block CB. Since the dummy drain regions 63 are not electrically connected to the bit lines 982, the dummy memory opening fill structures 158 comprise inactive (i.e., dummy) NAND strings which do not store data therein during the operation of the memory die 900.

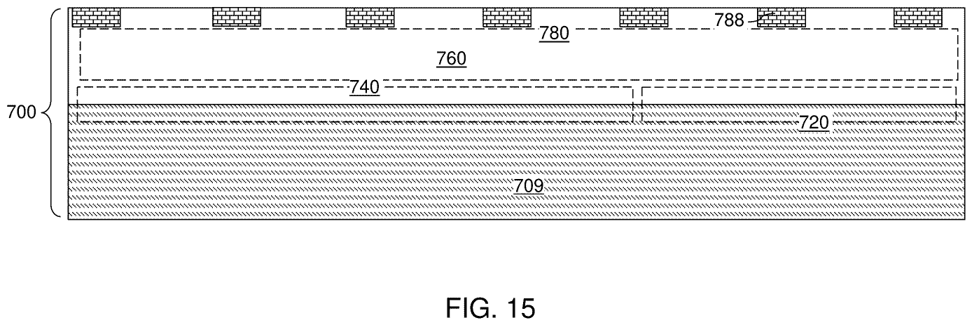

Referring to FIG. 15, a logic die 700 can be provided. The logic die 700 includes a logic-die substrate 709, a memory controller circuit 720 (which is also referred to as a peripheral circuit) located on the logic-die substrate 709 and comprising logic-die semiconductor devices (such as field effect transistors) configured to control the vertical NAND strings (e.g., memory opening fill structures 58), a charge pump circuit 740 configured to apply a high programming or erase voltage (or current) to the vertical NAND strings using the charge stored in the capacitor structures 90 in the memory die 900, logic-die metal interconnect structures 780 embedded within logic-die dielectric material layers 760, and logic-die bonding pads 788. The memory controller circuit 720 can be configured to control operation of the memory array within the memory die 900. Specifically, the memory controller circuit 720 can be configured to drive various electrical components within the memory array including, but not limited to, the electrically conductive layers 46, the drain regions 63 (e.g., via the bit lines 982), and source layers to be subsequently formed. Specifically, the memory controller circuit 720 can be used to program, read and erase memory cells (e.g., charge storage layer portions at levels of the word lines) of the vertical NAND strings 58.

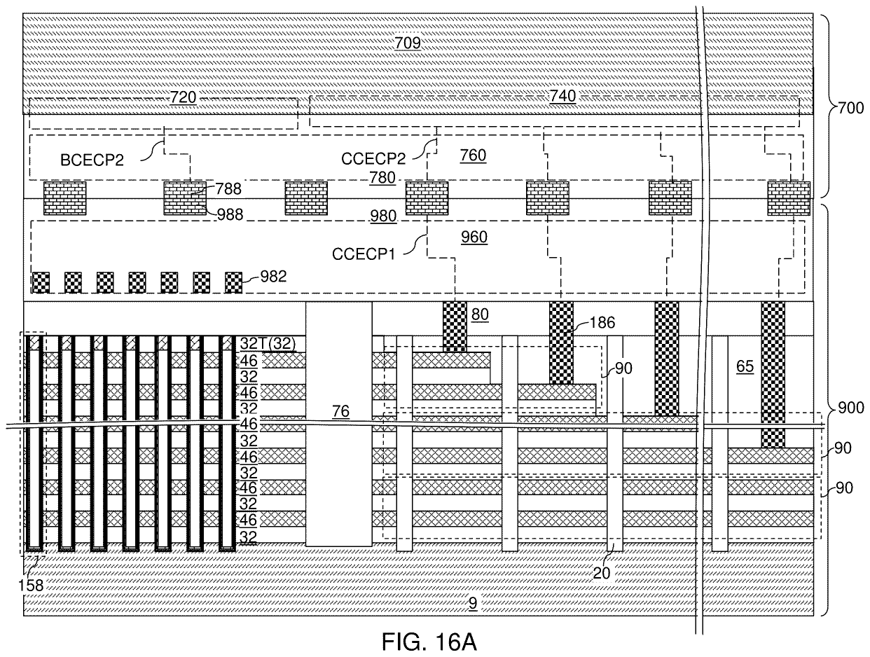

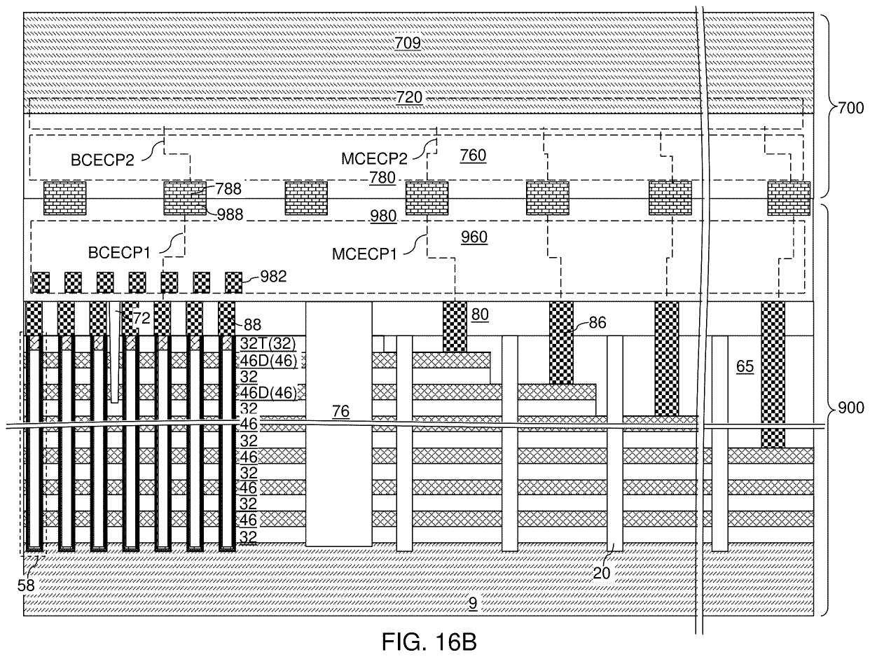

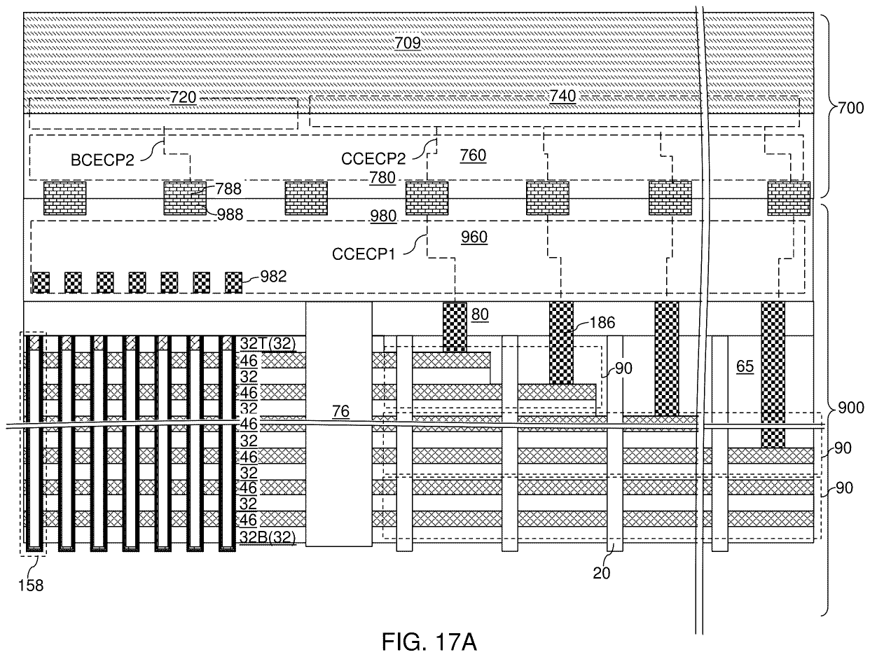

Referring to FIGS. 16A and 16B, the logic die 700 can be attached to the memory die 900, for example, by bonding the logic-die bonding pads 788 to the memory-die bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-wafer bonding process, or by a die-to-die bonding process. The logic-die bonding pads 788 within each logic die 700 can be bonded to the memory-die bonding pads 988 within a respective memory die 900.

According to an aspect of the present disclosure, a first subset of the logic-die metal interconnect structures 780 provides second capacitor connection electrically conductive paths CCECP2 between the charge pump circuit 740 and a first subset of the logic-die bonding pads 788 that are bonded to the first subset of the memory-die bonding pads 988. A second subset of the logic-die metal interconnect structures 780 provides second memory connection electrically conductive paths MCECP2 between the memory controller circuit 720 and a second subset of the logic-die bonding pads 788 that are bonded to the second subset of the memory-die bonding pads 988. A third subset of the logic-die metal interconnect structures 780 provides second bitline connection electrically conductive paths BCECP2 between the memory controller circuit 720 and a third subset of the logic-die bonding pads 788 that are bonded to the third subset of the memory-die bonding pads 988.

Thus, the electrode contact via structures 186 may be electrically connected to the charge pump circuit 740 through the first capacitor connection electrically conductive paths CCECP1 and the second capacitor connection electrically conductive paths CCECP2. The charge pump circuit 740 is electrically connected to each capacitor structure 90 within the first alternating stacks (32, 46) in the memory die 900, and may be configured to operate in a charge pump mode in which each capacitor structure 90 functions as a capacitor component of the charge pump circuit 740 to provide a high programming or erase current (or voltage) to the vertical NAND strings. In one embodiment, at least one first alternating stack (32, 46), at least one first retro-stepped dielectric material portion 65 that overlies stepped surfaces of a respective first alternating stack (32, 46), and the electrode contact via structures 186 are located within the memory die 900, while the charge pump circuit 740 is located within a logic die 700 that is bonded to the memory die 900.

The capacitor connection electrically conductive paths (CCECP1, CCECP2) between the charge pump circuit 740 and each of the first electrode contact via structure 186 and the second electrode contact via structure 186 for each neighboring pair of first electrically conductive layers 46 that function as capacitor electrodes may comprise a subset of memory-die metal interconnect structures 980 and a subset of logic-die metal interconnect structures 780.

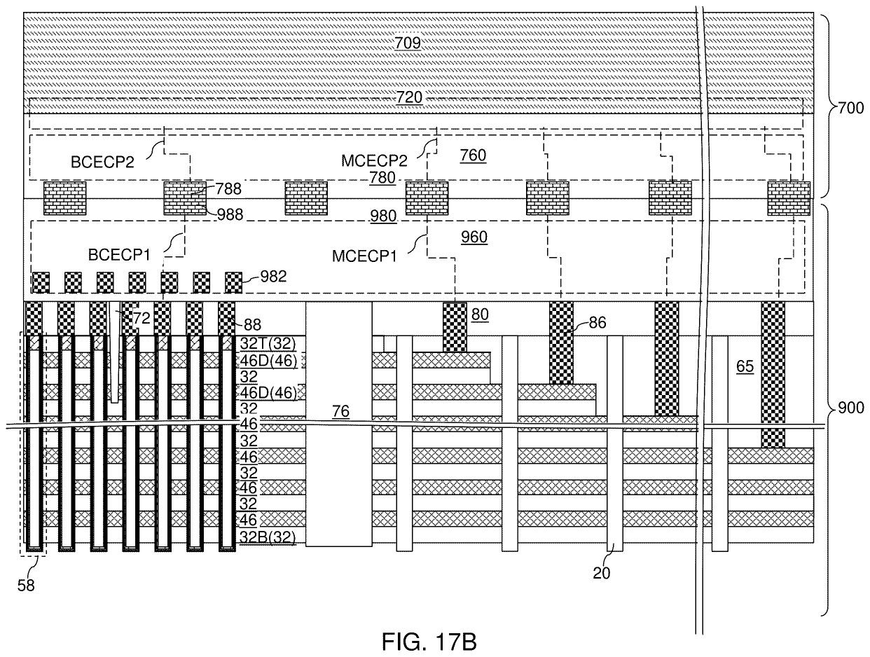

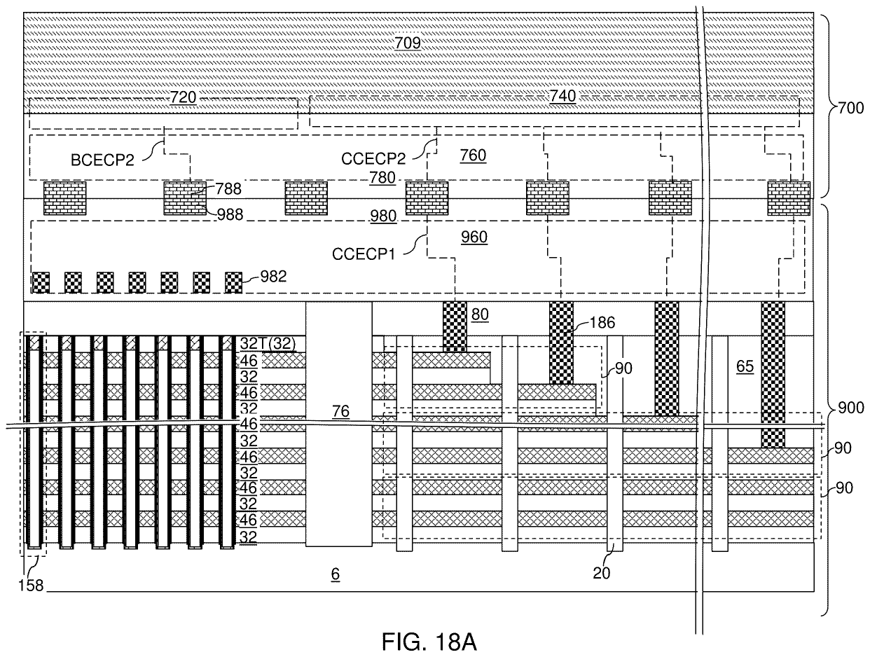

Referring to FIGS. 17A and 17B, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selectively to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Bottom end surfaces of the memory opening fill structures 58 and the dummy memory opening fill structures 158 can be physically exposed. Further, bottom end surfaces of the support pillar structures 20 can be physically exposed upon removal of the carrier substrate 9.

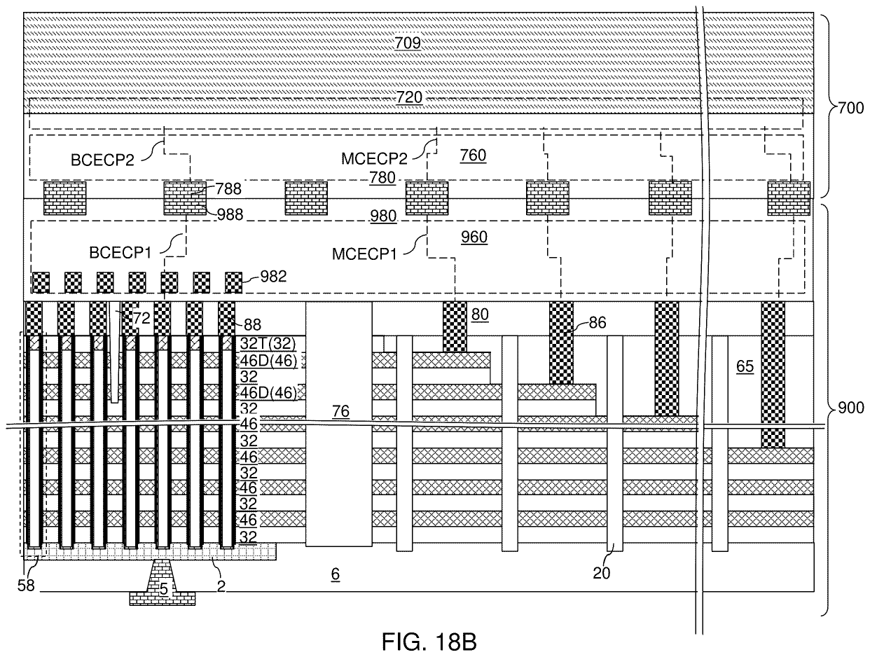

Referring to FIGS. 18A and 18B, a set of etch processes can be performed to sequentially etch unmasked portions of components layers of each memory film 50 that underlie the bottommost surface of the alternating stack (32, 46). In an illustrative example, if the memory film 50 comprises a blocking dielectric layer 52 composed of silicon oxide, if the memory material layer 54 comprises a charge storage layer including silicon nitride, and if the tunneling dielectric layer 56 comprises a tunneling dielectric layer including an ONO stack (i.e., a stack of a first silicon oxide layer, a silicon nitride layer, and a second silicon oxide layer), the set of etch processes may comprise a first wet etch process that etches physically exposed portions of the blocking dielectric layer 52 employing dilute hydrofluoric acid, a second wet etch process that etches physically exposed portions of the memory material layer 54 employing hot phosphoric acid, and a third chemical dry etch (CDE) process that etches the ONO stack of the tunneling dielectric layer. In one embodiment, the CDE process employs a plasma to generate reactive species that isotropically etch the exposed oxide and nitride layers of the ONO stack through chemical reactions, providing uniform material removal.

Generally, end portions of the blocking dielectric layer 52, the memory material layer 54, and the tunneling dielectric layer 56 can be removed from each memory opening fill structure 58 and from each dummy memory opening fill structure 158 to physically expose an end portion of a respective vertical semiconductor channel 60. The bottom surface of the bottommost insulating layer 32B may be collaterally recessed during removal of end portions of the memory films 50. In one embodiment, the bottom surface of the bottommost insulating layer 32B may be formed in a horizontal plane, below which end portions of the vertical semiconductor channels 60 extend vertically.

Subsequently, the first exemplary structure can be flipped upside down, and a source layer 2 can be formed on the physically exposed bottom end portions of the vertical semiconductor channels 60 in the memory opening fill structures 58. In one embodiment, the source layer 2 can be patterned such that the source layer does not contact any of the vertical semiconductor channels 60 in the dummy memory opening fill structures 158. The source layer 2 may comprise a heavily doped semiconductor layer, at least one metallic material layer, or a combination thereof.

A backside insulating layer 6 can be deposited on the source layer(s) 2, and physically exposed surfaces of the dummy memory opening fill structures 158. Contact structures, such as source contact structures 5, may be formed through the backside insulating layer 6 to the source layer(s) 2. Additional structures (not shown), such as bonding pads, may be formed as needed.

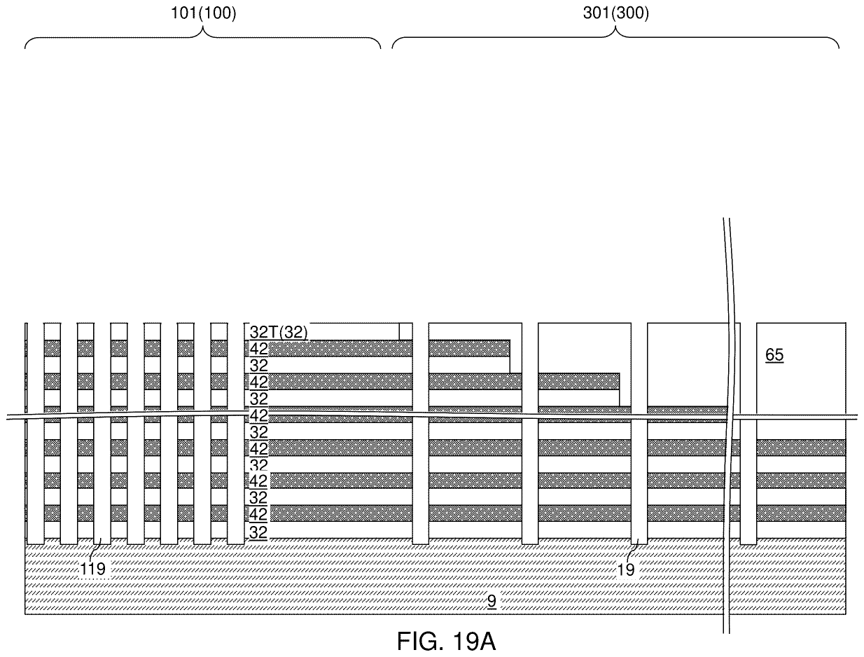

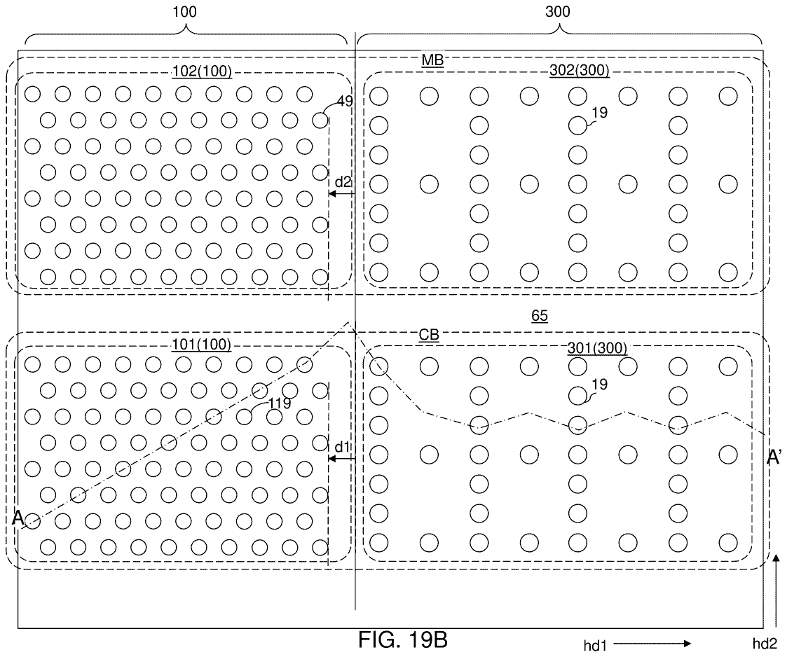

Referring to FIGS. 19A and 19B, a second exemplary structure according to an embodiment of the present disclosure is illustrated at a processing step that corresponds to the processing step described with reference to FIGS. 3A and 3B. In the second exemplary structure, pillar openings 119 are formed at locations of a first subset of the memory openings 49 within the first full-stack regions 101. In other words, pillar openings 119 are formed in lieu of memory openings 49 within the first full-stack regions 101 in the capacitor block CB. In the second exemplary structure, memory openings 49 are formed in the second full-stack regions 102 of the memory block MB as in the first exemplary structure.

In one embodiment, the pillar openings 119 may be structurally identical to a first subset of the memory openings 49 that are formed in the first full-stack regions 101 in the first exemplary structure. As such, the second exemplary structure in FIGS. 19A and 19B may be physically identical to the first exemplary structure illustrated of FIGS. 3A and 3B, and the first subset of the memory openings 49 in the first full-stack regions 101 are re-labeled as the pillar openings 119. In other words, the openings that are formed in the first full-stack regions 101 in the capacitor blocks CB are re-labeled as pillar openings 119 without any structural changes relative to the first exemplary structure illustrated in FIGS. 3A and 3B. In another embodiment, the lateral dimensions of the pillar openings 119 may be altered relative to the lateral dimensions of the memory openings 49 in the second exemplary structure.

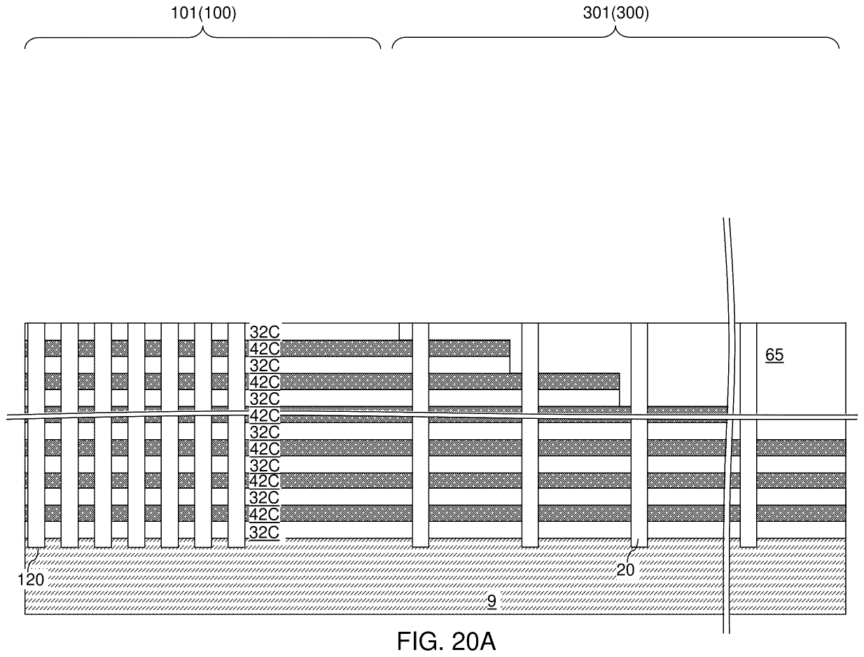

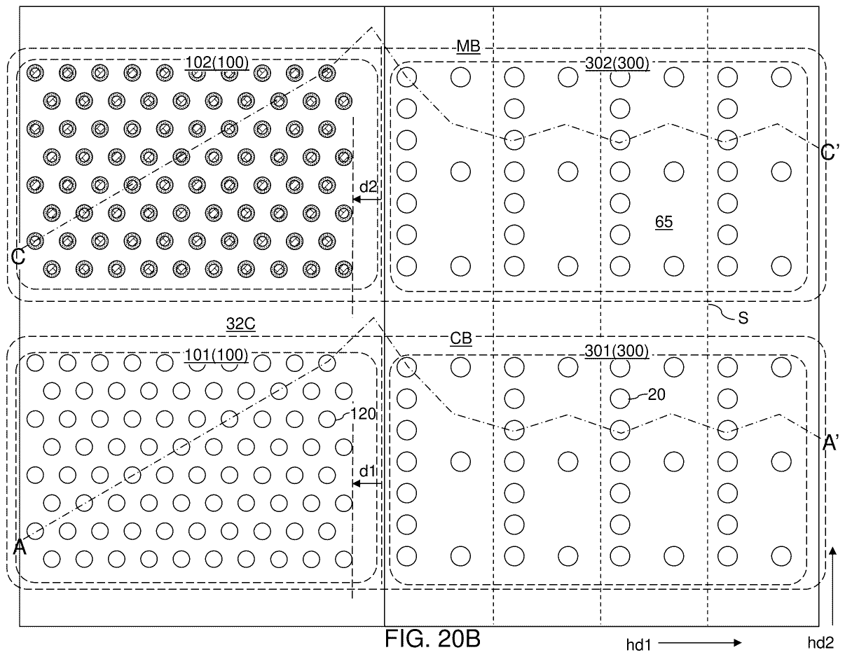

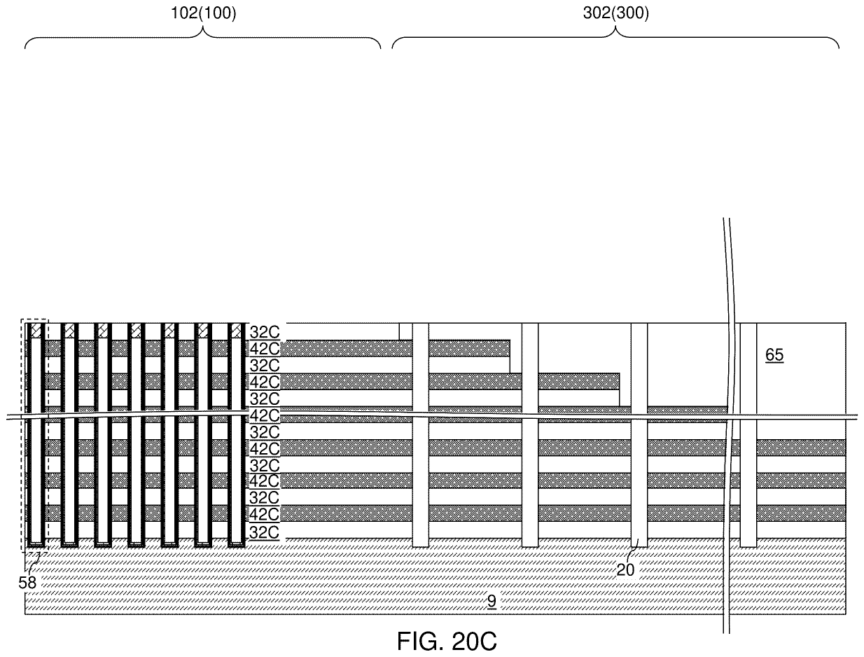

Referring to FIGS. 20A-20C, the processing steps described with reference to FIGS. 4-8C are performed with a modification that sacrificial opening fill structures 48 that are formed in the pillar openings 119 at a processing step corresponding to the processing steps of FIG. 4 are also removed during a processing step of FIG. 5 together with the sacrificial support opening fill structures 18. As a consequence, cavities are formed in the volumes of the pillar openings 119 during formation of cavities in the support openings 19 (i.e., the pillar openings 119 are reopened at the same time as the support openings 19). Thus, during deposition of a dielectric fill material in the support openings 19, the cavities in the pillar openings 119 are also filled with a respective portion of the dielectric fill material. Dielectric pillar structures 120 are formed in the pillar openings 119 during formation of the support pillar structures 20 in the support openings 19. The top surfaces of the dielectric pillar structures 120 and the top surfaces of the support pillar structures 20 may be formed within the horizontal plane including the top surface of the topmost continuous insulating layer 32C.

Subsequently, the processing steps described with reference to FIGS. 6-8C may be performed to replace the sacrificial memory opening fill structures 148 in the memory blocks MB with memory opening fill structures 58. First openings (such as the pillar openings 119) extend vertically through each layer in the vertically alternating sequence (32C, 42C) in the first full-stack region 101 of each capacitor block CB. In the second embodiment, first opening fill structures that fill the first openings 119 comprise dielectric pillar structures 120 having the same material composition as the support pillar structures 20 that vertically extend through the stepped surfaces and the retro-stepped dielectric material portion 65 in the staircase regions 300.

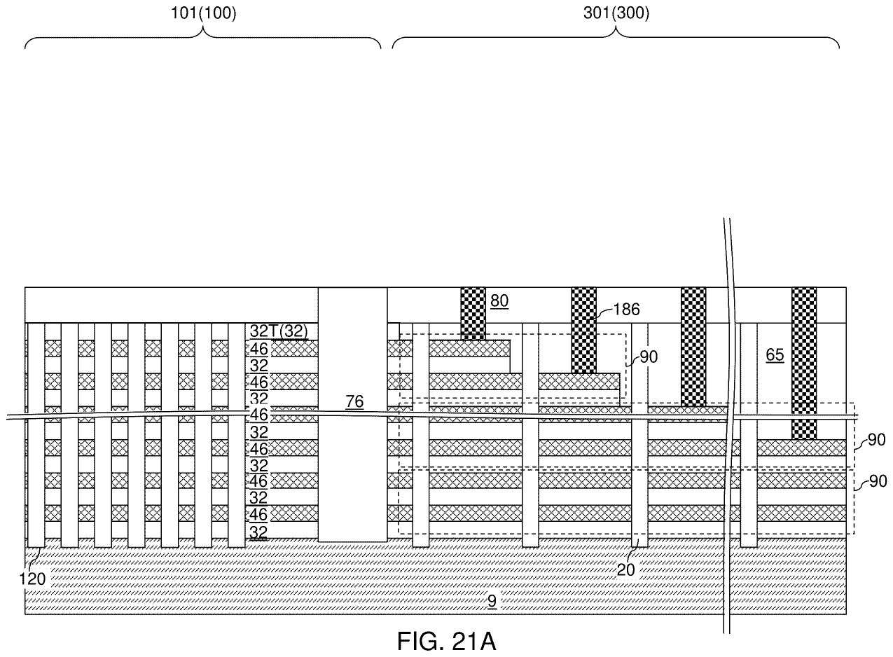

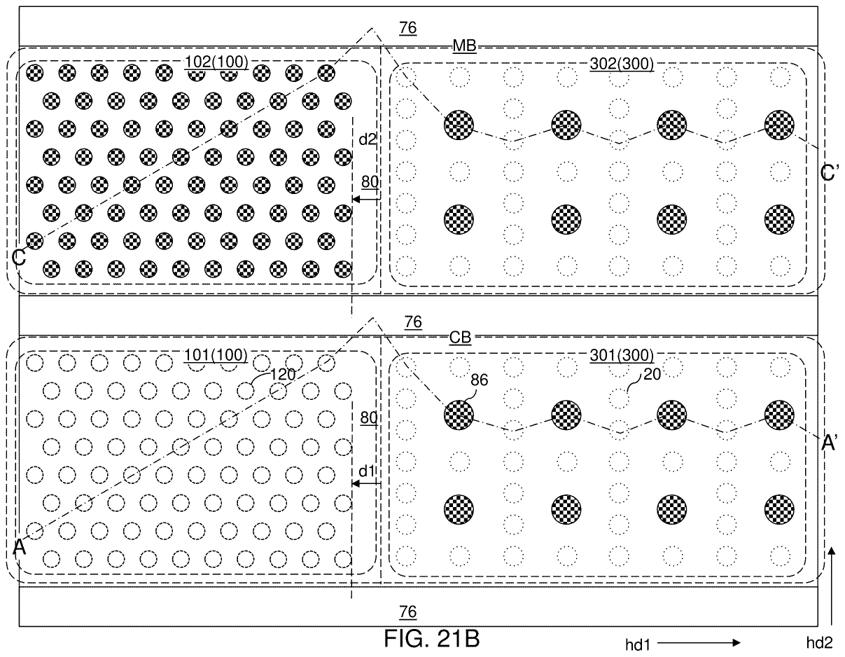

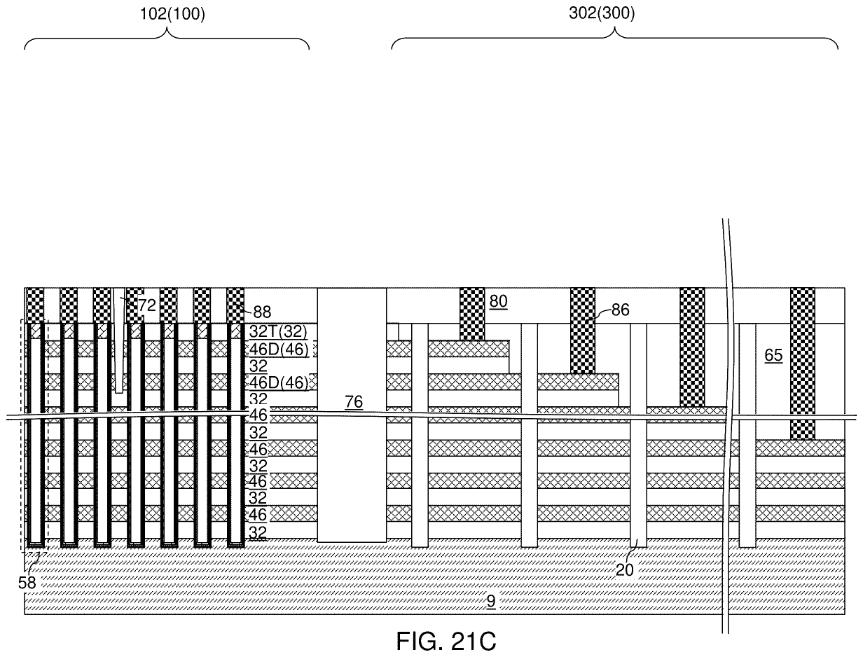

Referring to FIGS. 21A and 21B, the set of processing steps described with reference to FIGS. 9A-13C may be performed. In the second exemplary structure, the dummy memory opening fill structures 158 are replaced with the dielectric pillar structures 120 having the same material composition as the support pillar structures 20.

The second exemplary structure comprises a first alternating stack (32, 46) of first insulating layers 32 and first electrically conductive layers 46 that alternate along a vertical direction. The first alternating stack (32, 46) includes a first staircase region 301 with first stepped surfaces and a first full-stack region 101 where each layer within the first alternating stack (32, 46) is present. First openings extend vertically through each of the first insulating layers 32 and each of the first electrically conductive layers 46 in the first full-stack region 101. First opening fill structures fill the first openings. The first opening fill structures may be dielectric pillar structures 120.

A contact-level dielectric layer 80 overlies the first alternating stack (32, 46). The entirety of the top surfaces of the first opening fill structures may be in contact with the dielectric material of the contact-level dielectric layer 80. A first retro-stepped dielectric material portion 65 overlies the first stepped surfaces in the first staircase region 301. Lateral isolation trenches 79 which laterally extend along a first horizontal direction hd1 and have a uniform width along a second horizontal direction hd2 are filled with the lateral isolation trench fill structures.

A second alternating stack (32, 46) of second insulating layers 32 and second electrically conductive layers 46 is provided, which is laterally spaced from the first alternating stack (32, 46) by a lateral isolation trench 79. The second alternating stack may include a second staircase region with second stepped surfaces and a second full-stack region 102. Memory opening fill structures 58 are present in the second alternating stack (32, 46). Each of the memory opening fill structures 58 comprises a vertical semiconductor channel 60 and a vertical stack of memory elements.

The first stepped surfaces and second stepped surfaces may extend along the first horizontal direction hd1, with vertical steps that are parallel to the second horizontal direction hd2. A minimum lateral spacing along the first horizontal direction hd1 between a topmost vertical step within the first stepped surfaces and the first opening fill structures may be a first distance d1 that is greater than zero. A minimum lateral spacing along the first horizontal direction hd1 between a topmost vertical step within the second stepped surfaces and the memory opening fill structures 58 may be a second distance d2. The first distance d1 is not less than the second distance d2, and may be the same as the second distance d1. The topmost vertical step within the first stepped surfaces and the topmost vertical step within the second stepped surfaces may be contained entirely within a vertical Euclidian plane that is perpendicular to the first horizontal direction hd1.

According to an aspect of the present disclosure, at least one pair of a first electrode contact via structure 186 and a second electrode contact via structure 186 can be provided such that the first electrode contact via structure 186 and the second electrode contact via structure 186 may contact a vertically neighboring pair of first electrically conductive layers 46 within a first alternating stack (32, 46) to provide the capacitor structure 90. A vertical stack of a plurality of capacitor structures 90 can be formed in each capacitor block CB that is laterally bounded by a respective neighboring pair of lateral isolation trench fill structures 76. Each capacitor structure comprises a respective vertically neighboring pair of first electrically conductive layers 46 as a first electrode and a second electrode, and a respective intervening insulating layer 32 as a portion of the capacitor dielectric. In case outer blocking dielectric layers 44 are employed, each capacitor dielectric may also include horizontally-extending portions of two outer blocking dielectric layers 44 interposed between a respective vertically neighboring pair of first electrically conductive layers 46. Each first electrically conductive layer 46 in a capacitor structure 90 may comprise a respective array of first openings therethrough, which may be filled with a respective array of dielectric pillar structures 120.

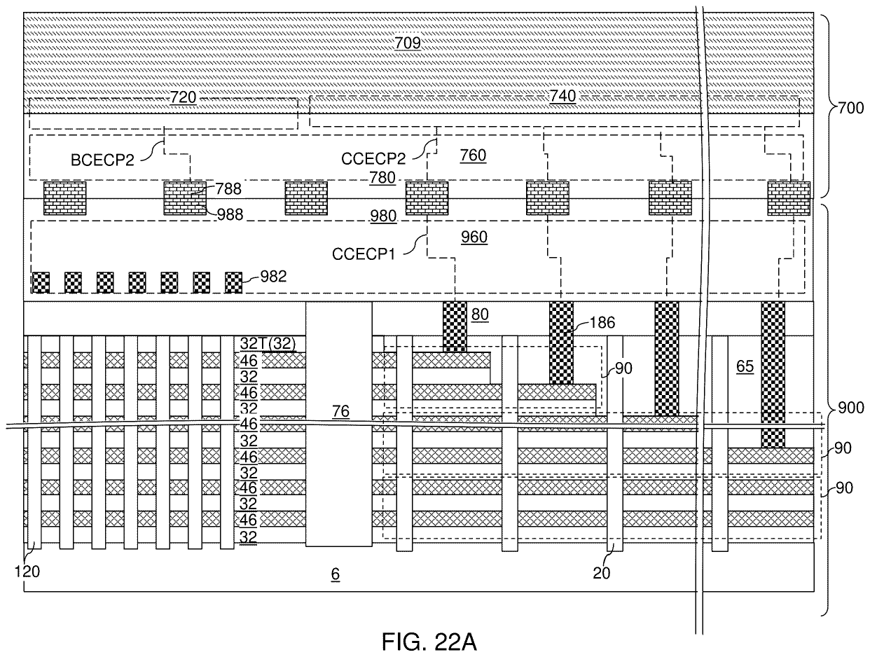

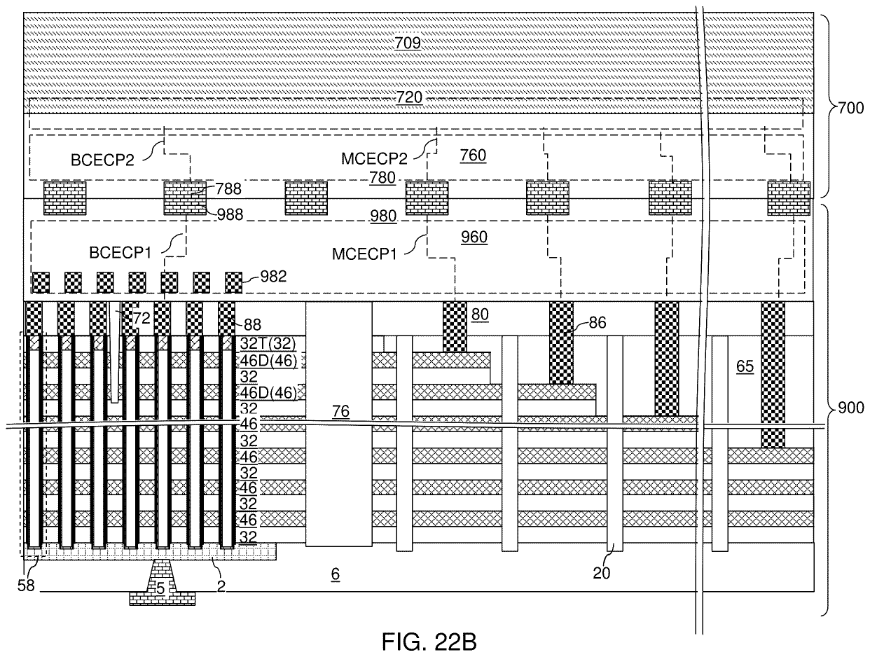

Referring to FIGS. 22A and 22B, the processing steps described with reference to FIGS. 14A-18B can be performed. The above described electrically conductive paths CCECP1, MCECP1 and BCECP1 may be provided as described above with respect to the first embodiment. The source layer 2, source contact structures 5, and the backside insulating layer 6 are then formed as described above.

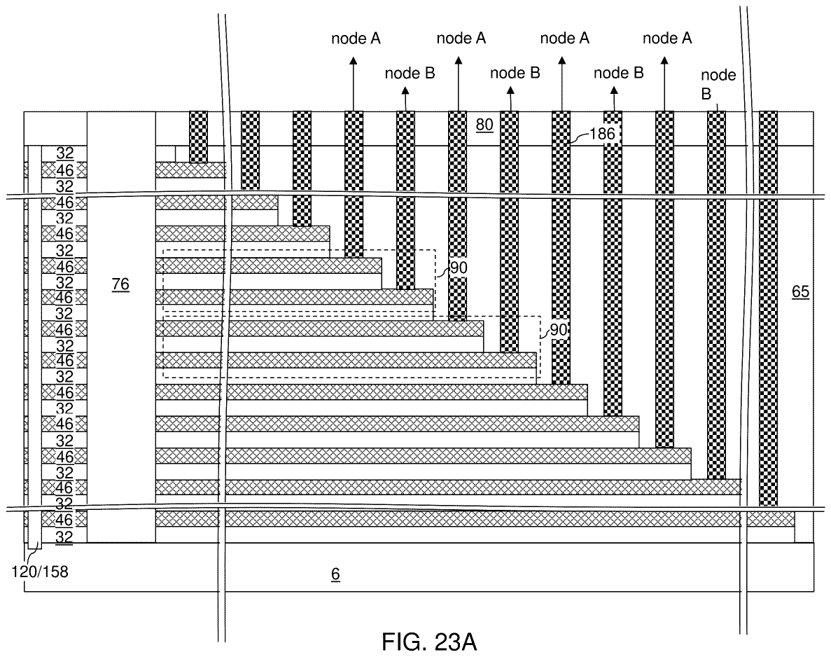

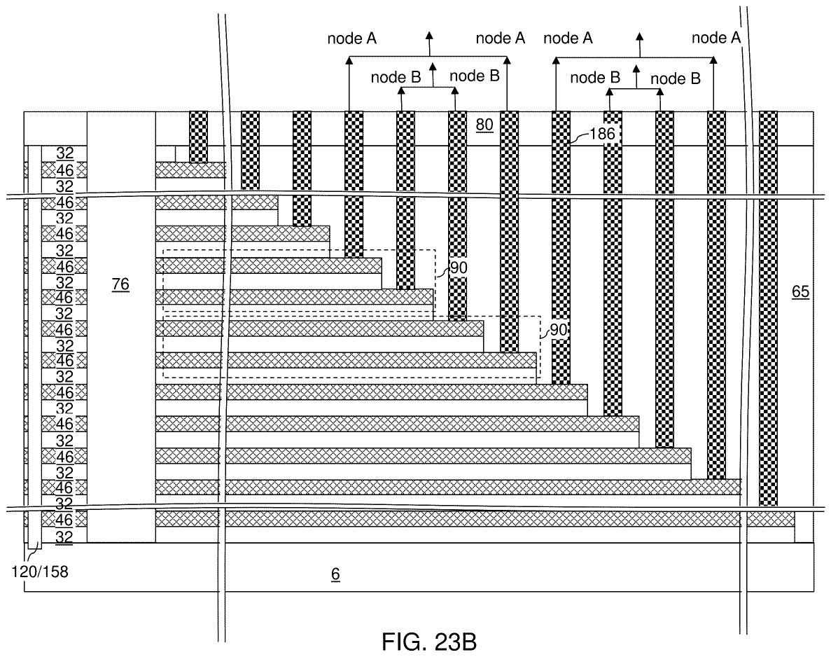

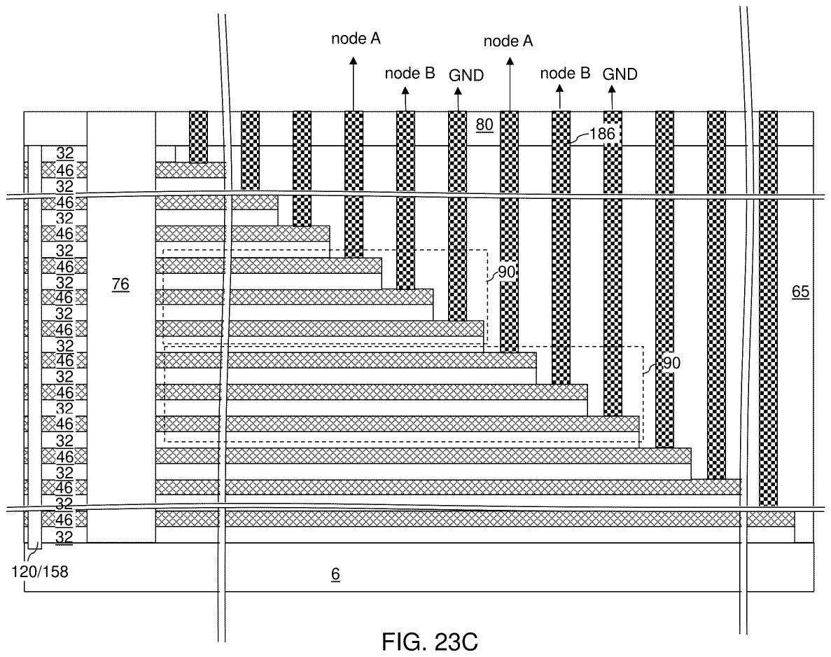

The capacitor structures 90 of the embodiments of the present disclosure may have any suitable electrical connections. Non-limiting illustrative examples of such electrical connections are shown in FIG. 23A-23C. The capacitor structures 90 comprises a primary electrode (node A), a complementary electrode (node B), and at least one capacitor dielectric, as shown in FIG. 23A. The relatively high charge, refresh and discharge voltage may be applied to the primary electrode via the charge pump circuit 740. The complementary electrode may be grounded or a relatively low complementary voltage may be applied to the complementary electrode during the charge, refresh and discharge operations.

In an alternative embodiment shown in FIG. 23B, the primary electrodes may be electrically connected to each other, and the complementary electrodes may be connected to each other. The electrically connected complementary electrodes may be grounded. In another embodiment shown in FIG. 23C, each capacitor structure 90 includes a separate ground electrode (GND) in addition to the primary electrode (node A) and the complementary electrode (node B). In this embodiment, a relatively low complementary voltage is applied to the complementary electrodes, while the ground electrodes are grounded.

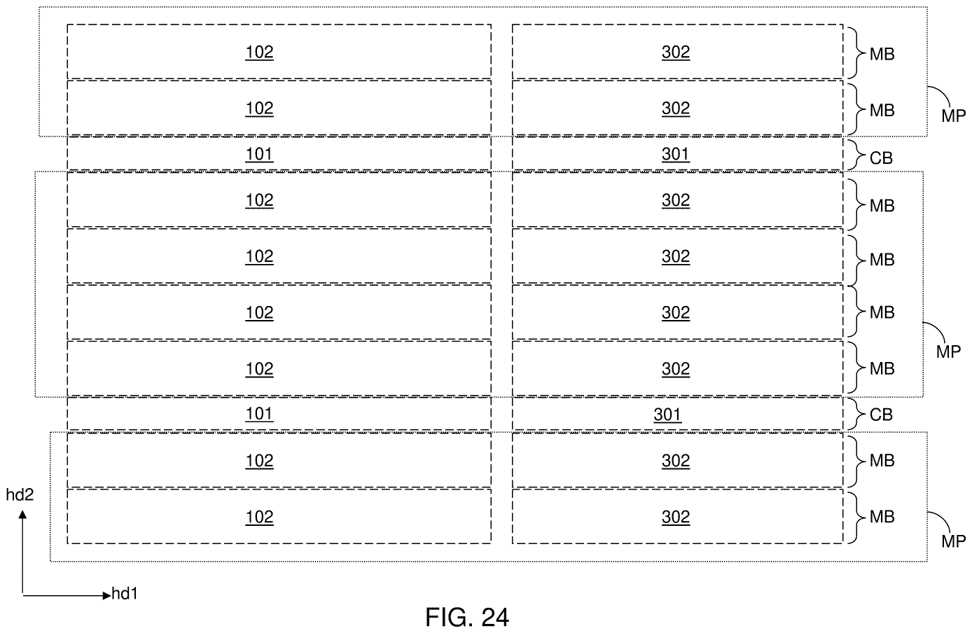

FIG. 24 is an exemplary layout that may be employed in the first and second exemplary structures according to first and second embodiments of the present disclosure. Generally, the capacitor blocks CB and the memory blocks MB may be interlaced along the second horizontal direction h2 in any order with lateral separation with lateral isolation trench fill structures 76 located there between. In one embodiment, the capacitor blocks CB may have a smaller width along the second horizontal direction hd2 than the memory blocks MB. In one embodiment, the capacitor blocks CB may comprise dummy memory blocks that are located between adjacent memory planes MP along the bit line direction hd2.

Referring to all drawings and according to various embodiments of the present disclosure, a semiconductor structure includes a capacitor block CB which comprises a first alternating stack (32, 46) of first insulating layers 32 and first electrically conductive layers 46 that alternate along a vertical direction. The first alternating stack (32, 46) comprises a first staircase region 301 including first stepped surfaces and further comprises a first full-stack region 101 in which each layer within the first alternating stack (32, 46) is present. The semiconductor structure includes first openings (which may be memory openings 49 or pillar openings 119) that vertically extend through each of the first insulating layers 32 and each of the first electrically conductive layers 46 in the first full-stack region 101. First opening fill structures (which may be dummy memory opening fill structures 158 or dielectric pillar structures 120) fill the first openings (49 or 119, respectively). Electrode contact via structures 186 contact a respective one of the first electrically conductive layers 46. A first electrode contact via structure 186 and a second electrode contact via structure 186 contact a vertically separated pair of first electrically conductive layers 46 within the first alternating stack (32, 46) to provide a capacitor structure 90 in which an intervening first insulating layer 32 of the first insulating layers 32 is a capacitor dielectric. The semiconductor structure further comprises a memory block MB that is laterally separated from the capacitor block CB. The memory block MP comprises a second alternating stack (32, 46) of second insulating layers 32 and second electrically conductive layers 46 that alternate along the vertical direction and laterally spaced from the first alternating stack (32, 46). The second alternating stack (32, 46) comprises a second staircase region 302 including second stepped surfaces, and a second full-stack region 102 in which each layer within the second alternating stack (32, 46) is present. The memory block MB also includes second openings (which are memory openings 49) that vertically extend through each of the second insulating layers 32 and each of the second electrically conductive layers 46 in the second full-stack region 102, and memory opening fill structures 58 that fill the second openings (i.e., the memory openings 49), wherein each of the memory opening fill structures 58 comprises a respective vertical semiconductor channel 60, a respective drain region 63 and a respective vertical stack of memory elements (which may comprise portions of a respective memory material layer 54).

In one embodiment, the semiconductor structure further comprises bit lines 982 extending along a bit line direction hd2 over the capacitor block CB and over the memory block MB. Each of drain regions 63 of the memory opening fill structures 58 is electrically connected to a respective one of the bit lines 982, and the first opening fill structures (158 or 120) are not electrically connected to the bit lines 982.

In one embodiment, the semiconductor structure further comprises a charge pump circuit 740 electrically connected to the capacitor structure 90 and configured function as a capacitor component of the charge pump circuit 740. In one embodiment, the memory block MB and the capacitor block CB are located within a memory die 900. The charge pump circuit 740 may be located within a logic die 700 that is bonded to the memory die 900.

In one embodiment, the memory die 900 may also comprise memory-die dielectric material layers 960 embedding memory-die metal interconnect structures 980 and the bit lines 982, and interposed between the first alternating stack (32, 46) and the logic die 700. The logic die 700 may comprise logic-die dielectric material layers 760 embedding logic-die metal interconnect structures 780 and interposed between the charge pump circuit 740 and the memory die 900. In one embodiment, electrically conductive paths (such as the first capacitor connection electrically conductive paths CCECP1 and the second capacitor connection electrically conductive paths CCECP2) may be provided between the charge pump circuit 740 and each of the first electrode contact via structure 186 and the second electrode contact via structure 186. The electrically conductive paths may comprise a subset of the memory-die metal interconnect structures 980 and a subset of the logic-die metal interconnect structures 780.

In one embodiment, the semiconductor structure may further comprise a first retro-stepped dielectric material portion 65 overlying the first stepped surfaces, wherein each of the first electrode contact via structure 186 and the second electrode contact via structure 186 vertically extends through the first retro-stepped dielectric material portion 65.

In the first embodiment, the first opening fill structures comprise dummy memory opening fill structures 158. Each of the dummy memory opening fill structures 158 may comprise a respective vertical semiconductor channel 60, a respective dummy drain region 63, and a respective vertical stack of dummy memory elements (which may comprise portions of a respective memory material layer 54) located at levels of the first electrically conductive layers 46 and laterally surrounding the respective vertical semiconductor channel 60. The dummy drain regions 63 are not electrically connected to the bit lines 982.

In the second embodiment, the first opening fill structures comprise dielectric pillar structures 120 consisting of at least one dielectric fill material.

In one embodiment, the semiconductor structure may further comprise a contact-level dielectric layer 80 overlying the first alternating stack (32, 46) and comprising a dielectric material, wherein an entirety of top surfaces of the first opening fill structures (which may be dummy memory opening fill structures 158 or dielectric pillar structures 120) are in contact with the dielectric material of the contact-level dielectric layer 80.

In one embodiment, the memory block MB is laterally offset from the capacitor block CB along the bit line direction hd2. In one embodiment, the second electrically conductive layers 46 comprise word lines and select gate electrodes which extend along a word line direction hd1 which is perpendicular to the bit line direction hd2; and the first electrically conductive layers 46 comprise capacitor structure 90 electrodes which extend along the word line direction hd1. Each of the first stepped surfaces and the second stepped surfaces may laterally extend along the word line direction hd1. Vertical steps within the first stepped surfaces and the second stepped surfaces may be parallel to the bit line direction hd2. In one embodiment, a minimum lateral spacing along the word line direction hd1 between a topmost vertical step within the first stepped surfaces and the first opening fill structures (which may be dummy memory opening fill structures 158 or dielectric pillar structures 120) may be a first distance d1 that is greater than zero. In one embodiment, a minimum lateral spacing along the word line direction hd1 between a topmost vertical step within the second stepped surfaces and the memory opening fill structures 58 may be a second distance d2 that is not greater than the first distance d1. In one embodiment, the topmost vertical step within the first stepped surfaces and a topmost vertical step within the second stepped surfaces may be located within a same Euclidean vertical plane that is perpendicular to the word line direction hd1.

In one embodiment, each of the vertical semiconductor channels 60 of the memory opening fill structures 58 may comprise a respective bottom surface in contact with a source layer 2. An entirety of bottom surfaces of the first opening fill structure may be in contact with a respective backside insulating layer 6 that underlies the first alternating stack (32, 46).

In one embodiment, the second alternating stack (32, 46) may be laterally spaced from the first alternating stack (32, 46) by a lateral isolation trench 79 that laterally extends along the word line direction hd1. A lateral isolation trench fill structure 76 may be located within the lateral isolation trench 79.

Embodiments of the present disclosure facilitate memory device scaling by providing capacitor structures 90 in dummy memory blocks of a memory die 900. The dummy memory blocks may be located between adjacent memory planes MP along the bit line direction. Thus, capacitor structures 90 can be formed within the capacitor blocks CB (i.e., unused dummy memory blocks) located between active memory blocks MB in the memory die 900 to reduce the size of the charge pump circuit 740 in the logic die 700 without negatively affecting the area available for active memory blocks MB.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a capacitor block comprising:
a first alternating stack of first insulating layers and first electrically conductive layers that alternate along a vertical direction, wherein the first alternating stack comprises a first staircase region including first stepped surfaces and further comprises a first full-stack region in which each layer within the first alternating stack is present;
first openings that vertically extend through each of the first insulating layers and each of the first electrically conductive layers in the first full-stack region;
first opening fill structures that fill the first openings;
electrode contact via structures contacting a respective one of the first electrically conductive layers, wherein a first and a second layer contact via structures of the electrode contact via structures contact a vertically separated pair of first electrically conductive layers within the first alternating stack to provide a capacitor structure in which an intervening first insulating layer of the first insulating layers is a capacitor dielectric; and
a memory block laterally separated from the capacitor block, the memory block comprising:
a second alternating stack of second insulating layers and second electrically conductive layers that alternate along the vertical direction and laterally spaced from the first alternating stack, wherein the second alternating stack comprises a second staircase region including second stepped surfaces, and further comprises a second full-stack region in which each layer within the second alternating stack is present;
second openings that vertically extends through each of the second insulating layers and each of the second electrically conductive layers in the second full-stack region; and
memory opening fill structures that fill the second openings, wherein each of the memory opening fill structures comprises a respective vertical semiconductor channel, a respective drain region, and a respective vertical stack of memory elements.

2. The semiconductor structure of claim 1, further comprising bit lines extending along a bit line direction over the capacitor block and over the memory block, wherein each of drain regions of the memory opening fill structures is electrically connected to a respective one of the bit lines, and the first opening fill structures are not electrically connected to the bit lines.

3. The semiconductor structure of claim 2, further comprising a charge pump circuit electrically connected to the capacitor structure, wherein the capacitor structure is configured to function as a capacitor component of the charge pump circuit.

4. The semiconductor structure of claim 3, wherein:
the memory block and the capacitor block are located within a memory die; and
the charge pump circuit is located within a logic die that is bonded to the memory die.

5. The semiconductor structure of claim 4, wherein:
the memory die further comprises memory-die dielectric material layers embedding memory-die metal interconnect structures and the bit lines, wherein the memory-die dielectric material layers are interposed between the first alternating stack and the logic die;
the logic die comprises logic-die dielectric material layers embedding logic-die metal interconnect structures and interposed between the charge pump circuit and the memory die; and
electrically conductive paths between the charge pump circuit and each of the first electrode contact via structure and the second electrode contact via structure comprise a subset of the memory-die metal interconnect structures and a subset of the logic-die metal interconnect structures.

6. The semiconductor structure of claim 2, further comprising a first retro-stepped dielectric material portion overlying the first stepped surfaces, wherein each of the first electrode contact via structure and the second electrode contact via structure vertically extends through the first retro-stepped dielectric material portion.

7. The semiconductor structure of claim 2, wherein:
the first opening fill structures comprise dummy memory opening fill structures;
each of the dummy memory opening fill structures comprises a respective vertical semiconductor channel, a respective dummy drain region, and respective vertical stack of dummy memory elements located at levels of the first electrically conductive layers and laterally surrounding the respective vertical semiconductor channel; and
the dummy drain regions are not electrically connected to the bit lines.

8. The semiconductor structure of claim 2, wherein the first opening fill structures comprise dielectric pillar structures consisting of at least one dielectric fill material.

9. The semiconductor structure of claim 2, further comprising a contact-level dielectric layer overlying the first alternating stack and comprising a dielectric material, wherein an entirety of top surfaces of the first opening fill structures are in contact with the dielectric material of the contact-level dielectric layer.

10. The semiconductor structure of claim 2, wherein the memory block is laterally offset from the capacitor block along the bit line direction.

11. The semiconductor structure of claim 10, wherein:
the second electrically conductive layers comprise word lines and select gate electrodes which extend along a word line direction which is perpendicular to the bit line direction; and
the first electrically conductive layers comprise capacitor structure electrodes which extend along the word line direction.

12. The semiconductor structure of claim 11, wherein:
each of the first stepped surfaces and the second stepped surfaces laterally extend along the word line direction;
vertical steps within the first stepped surfaces and the second stepped surfaces are parallel to the bit line direction; and
a minimum lateral spacing along the word line direction between a topmost vertical step within the first stepped surfaces and the first opening fill structures is a first distance that is greater than zero.

13. The semiconductor structure of claim 12, wherein a minimum lateral spacing along the word line direction between a topmost vertical step within the second stepped surfaces and the memory opening fill structures is a second distance that is not greater than the first distance.

14. The semiconductor structure of claim 12, wherein the topmost vertical step within the first stepped surfaces and a topmost vertical step within the second stepped surfaces are located within a same Euclidean vertical plane that is perpendicular to the word line direction.

15. The semiconductor structure of claim 11, wherein:
each of the vertical semiconductor channels of the memory opening fill structures comprises a respective bottom surface in contact with a source layer; and
an entirety of bottom surfaces of the first opening fill structures are in contact with a respective backside insulating layer that underlies the first alternating stack.

16. The semiconductor structure of claim 10, wherein:
the second alternating stack is laterally spaced from the first alternating stack by a lateral isolation trench that laterally extends along the word line direction; and
a lateral isolation trench fill structure is located within the lateral isolation trench.

17. A method of forming a semiconductor structure, comprising:
forming a vertically alternating sequence of continuous insulating layers and continuous sacrificial material layers over a substrate, the vertically alternating sequence comprising a first full-stack region and a second full-stack region;
forming first openings in the first full-stack region and forming second openings in the second full-stack region;
forming first opening fill structures that fill the first openings, and forming memory opening fill structures in the second openings, wherein each of the memory opening fill structures comprises a respective vertical semiconductor channel, a respective drain region and a respective vertical stack of memory elements;
forming lateral isolation trenches that divide vertically alternating sequence;
replacing remaining portions of continuous sacrificial material layers with at least one electrically conductive material through the lateral isolation trenches to form a first alternating stack of first insulating layers and first electrically conductive layers in an area of the first full-stack region and to form a second alternating stack of second insulating layers and second electrically conductive layers in an area of the second full-stack region;
forming electrode contact via structures is contact with respective the first electrically conductive layers, wherein a first and a second layer contact via structures of the electrode contact via structures contact a vertically separated pair of first electrically conductive layers within the first alternating stack to provide a capacitor structure in which an intervening first insulating layer of the first insulating layers is a capacitor dielectric; and
forming bit lines extending along a bit line direction over the first alternating stack and the second alternating stack, wherein each of drain regions of the memory opening fill structures is electrically connected to a respective one of the bit lines, and the first opening fill structures are not electrically connected to the bit lines.

18. The method of claim 17, further comprising:
forming continuous stepped surfaces by patterning the vertically alternating sequence; and
forming a continuous retro-stepped dielectric material portion over the continuous stepped surface, wherein the electrode contact via structures are formed through a portion of the continuous retro-stepped dielectric material portion.

19. The method of claim 17, further comprising:
forming memory-die metal interconnect structures embedded in memory-die dielectric material layers over the first alternating stack and the second alternating stack to form a memory die;
providing a logic die comprising a charge pump circuit and logic-die metal interconnect structures embedded in logic-die dielectric material layers; and
bonding the logic die and the memory die to form electrically conductive paths between the capacitor structure and the charge pump circuit.

20. The method of claim 17, wherein:
the first alternating stack is located in a capacitor block;
the second alternating stack is located in a memory block that is laterally separated from the capacitor block along the bit line direction by a lateral isolation trench fill structure;
the first opening fill structures comprise dummy memory opening fill structures;
each of the dummy memory opening fill structures comprises a respective vertical semiconductor channel, a respective dummy drain region, and respective vertical stack of dummy memory elements located at levels of the first electrically conductive layers and laterally surrounding the respective vertical semiconductor channel; and
the dummy drain regions are not electrically connected to the bit lines.
